(19) United States
(12) Patent Application Publication
(10) Pub. No.: US 2024/0120266 A1
(43) Pub. Date: Apr. 11, 2024

(54) SEMICONDUCTOR PACKAGE INCLUDING CONDUCTIVE ANTIOXIDANT LAYER

(71) Applicant: SAMSUNG-RO, YEONGTONG-GU, Suwon-si (KR)

(72) Inventors: Sujung HYUNG, Suwon-si (KR); Myoungchul EUM, Suwon-si (KR); Chiwoo LEE, Suwon-si (KR)

(21) Appl. No.: 18/369,258

(22) Filed: Sep. 18, 2023

(30) Foreign Application Priority Data
Oct. 6, 2022 (KR) 10-2022-0128082

(51) Int. Cl. H01L 23/498; H01L 23/00; H01L 23/29; H01L 23/31; H01L 25/10

(52) U.S. Cl. CPC H01L 23/49838; H01L 23/295; H01L 23/3107; H01L 23/49822; H01L 23/49866; H01L 24/16; H01L 24/32; H01L 24/73; H01L 25/105; H01L 2224/16227; H01L 2224/16238; H01L 2224/32225; H01L 2224/73204; H01L 2225/1023; H01L 2225/1041; H01L 2225/1058; H01L 2924/15174; H01L 2924/35121

(57) ABSTRACT

Provided is a semiconductor package including a first distribution structure, which includes a plurality of first distribution patterns disposed between a plurality of first lower surface connection pads and a plurality of first upper surface connection pads, and a first base insulating layer surrounding the plurality of first distribution patterns. The semiconductor package further includes a second distribution structure including a plurality of second distribution patterns disposed between a plurality of second lower surface connection pads and a plurality of second upper surface connection pads, and a second base insulating layer surrounding the plurality of second distribution patterns. The semiconductor package further includes a plurality of connection structures configured to penetrate the encapsulant and disposed adjacent to the semiconductor chip, wherein the connection structure includes a conductive antioxidant layer covering side surfaces of the conductive post.

### CROSS-REFERENCE TO RELATED APPLICATION

This U.S. nonprovisional patent application claims priority under 35 U.S.C. § 119 to Korean Patent Application No. 10-2022-0128082, filed on Oct. 6, 2022, in the Korean Intellectual Property Office, the disclosure of which is incorporated by reference herein in its entirety.

### TECHNICAL FIELD

Embodiments of the present inventive concept relates to a semiconductor package, and more particularly, to a fan out-type semiconductor package including a conductive antioxidant layer.

### DISCUSSION OF RELATED ART

In response to the rapid development in the electronics industry and the needs of users, electronic devices are further miniaturized and multi-functionalized, and have a large capacity. Accordingly, highly integrated semiconductor chips are required.

Accordingly, to obtain highly integrated semiconductor chips with an increased number of connection terminals for input/output (I/O), semiconductor packages including connection terminals having connection reliability have been devised, and for example, to prevent interference between the connection terminals. As a result, a fan out-type semiconductor package with an increased gap between connection terminals has been developed.

### SUMMARY

Provided is a semiconductor package including a first distribution structure, which includes a plurality of first distribution patterns disposed between a plurality of first lower surface connection pads and a plurality of first upper surface connection pads, and a first base insulating layer surrounding the plurality of first distribution patterns. The semiconductor package further includes a second distribution structure including a plurality of second distribution patterns disposed between a plurality of second lower surface connection pads and a plurality of second upper surface connection pads, and a second base insulating layer surrounding the plurality of second distribution patterns. In some embodiment, a semiconductor chip is disposed between the first distribution structure and the second distribution structure. An encapsulant fills a space between the first distribution structure and the second distribution structure and surrounding the semiconductor chip. The semiconductor package further includes a plurality of connection structures configured to penetrate the encapsulant and disposed adjacent to the semiconductor chip, wherein a connection structure of the plurality of connection structures includes a conductive post extending in a vertical direction to electrically connect a first upper surface connection pad of the plurality of first upper surface connection pads and a second lower surface connection pad of the plurality of second lower surface connection pads, and the connection structure includes a conductive antioxidant layer covering side surfaces of the conductive post.

Provided is a semiconductor package including a first distribution structure, which includes a plurality of first distribution patterns disposed between a plurality of first lower surface connection pads and a plurality of first upper surface connection pads, and a first base insulating layer surrounding the plurality of first distribution patterns. The semiconductor package further includes a second distribution structure including a plurality of second distribution patterns disposed between a plurality of second lower surface connection pads and a plurality of second upper surface connection pads, and a second base insulating layer surrounding the plurality of second distribution patterns. The semiconductor package further includes a semiconductor chip disposed between the first distribution structure and the second distribution structure, wherein a plurality of chip pads is disposed on a bottom surface of the semiconductor chip. The semiconductor package further includes a plurality of connection structures connecting some of the plurality of first upper surface connection pads to some of the plurality of second lower surface connection pads and disposed adjacent to the semiconductor chip, wherein a connection structure of the plurality of connection structures includes a conductive post extending in a vertical direction and a conductive antioxidant layer covering side surfaces of the conductive post. The semiconductor package further includes a plurality of chip connection members connecting remaining ones of the plurality of first upper surface connection pads and the plurality of chip pads, and an encapsulant surrounding the plurality of connection structures and the semiconductor chip, filling a space among the first distribution structure, the second distribution structure, and the conductive antioxidant layer, and spaced apart from the conductive post.

Provided is a semiconductor package including a first distribution structure, which includes a plurality of first distribution patterns disposed between a plurality of first lower surface connection pads and a plurality of first upper surface connection pads, and a first redistribution insulating layer surrounding the plurality of first distribution patterns. The semiconductor package further includes a semiconductor chip disposed on the first redistribution structure, wherein a plurality of chip pads is disposed on a bottom surface of the semiconductor chip. The semiconductor package further includes a second redistribution structure disposed on the semiconductor chip and the first redistribution structure, and is spaced apart from the semiconductor chip in a vertical direction, wherein the second redistribution structure includes a plurality of second redistribution patterns including a plurality of second lower surface connection pads, a plurality of second upper surface connection pads, and a second redistribution insulating layer surrounding the plurality of second redistribution patterns. The semiconductor package further includes a plurality of connection structures disposed adjacent to the semiconductor chip and connecting some of the plurality of first upper surface connection pads to the plurality of second lower surface connection pads, wherein a connection structure of the plurality of connection structures includes a conductive post extending in a vertical direction and a conductive antioxidant layer covering side surfaces and a lower surface of the conductive post. The semiconductor package further includes a plurality of chip connection members connecting remaining ones of the plurality of first upper surface connection pads and the plurality of chip pads, wherein a chip connection member of the plurality of chip connection members includes an under bump metal (UBM) layer disposed on the plurality of chip pads and a conductive cap covering the UBM layer. The semiconductor package further includes a plurality of external connection terminals respectively connected to the plurality of first lower surface connection pads, and an encapsulant filling a space between the first distribution structure and the second redistribution structure, surrounding the plurality of connection structures, the semiconductor chip, and the conductive antioxidant layer, and spaced apart from the conductive post.

### BRIEF DESCRIPTION OF THE DRAWINGS

FIG. 1 is a cross-sectional view of a semiconductor package according to an embodiment of the present inventive concept;

FIGS. 2A, 2B, 2C, 2D, 2E, 2F, 2G, 2H, 2I, and 2J are cross-sectional views illustrating a method of manufacturing a semiconductor package, according to embodiments of the present inventive concept;

FIG. 3 is a cross-sectional view of a semiconductor package according to an embodiment of the present inventive concept;

FIGS. 4A, 4B, 4C, 4D, 4E, 4F, 4G, and 4H are cross-sectional views illustrating a method of manufacturing a semiconductor package, according to embodiments of the present inventive concept;

FIGS. 5 and 6 are cross-sectional views of semiconductor packages according to embodiments of the present inventive concept; and

FIGS. 7, 8, 9, and 10 are cross-sectional views of semiconductor packages, according to embodiments of the present inventive concept.

### DETAILED DESCRIPTION OF THE EMBODIMENTS

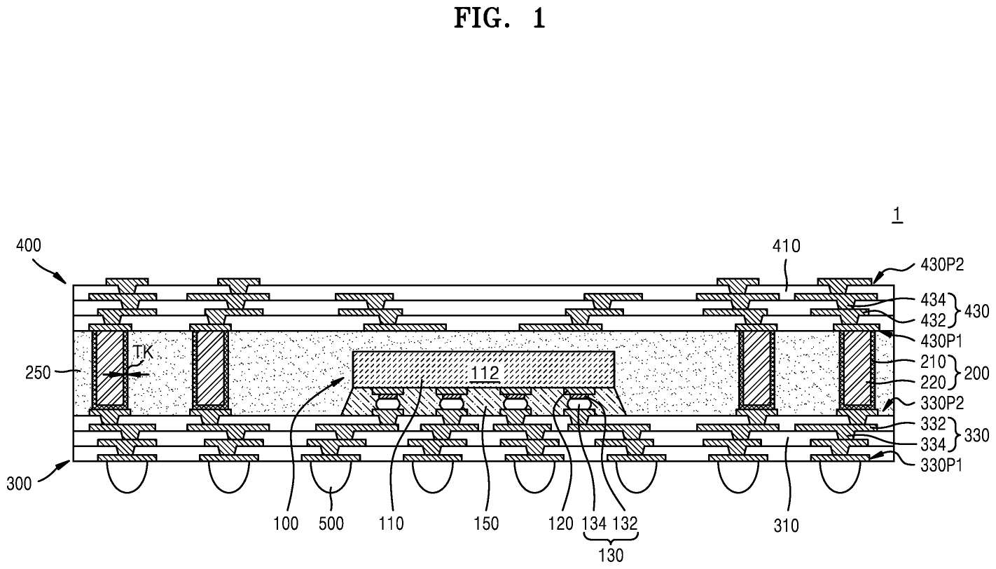

FIG. 1 is a cross-sectional view of a semiconductor package 1 according to an embodiment of the present inventive concept.

Referring to FIG. 1, the semiconductor package 1 may include a first distribution structure 300, a second distribution structure 400 disposed on the first distribution structure 300, and at least one semiconductor chip 100 disposed between the first distribution structure 300 and the second distribution structure 400. In some embodiments, the semiconductor package 1 may include a lower package of a package-on-package (PoP). The semiconductor package 1 may include a fan out-type semiconductor package in which a horizontal width and a horizontal area of the first distribution structure 300 are respectively greater than a horizontal width and a horizontal area of a footprint of at least one semiconductor chip 100. In some embodiments, the semiconductor package 1 may have a fan out-type wafer level package (FOWLP) or a fan out-type panel level package (FOPLP).

In some embodiments, at least one of the first distribution structure 300 and the second distribution structure 400 may be formed by performing a redistribution process. In some aspect, the first distribution structure 300 may be referred to as a first redistribution structure or a lower redistribution structure. The second distribution structure 400 may be referred to as a second distribution structure or an upper redistribution structure.

The first distribution structure 300 may include a first redistribution insulating layer 310 and a plurality of first redistribution patterns 330. The first redistribution insulating layers 310 may surround the plurality of first redistribution patterns 330. For example, the plurality of first redistribution patterns 330 may be disposed between each of the first redistribution insulating layers 310, vertically and/or horizontally. In some embodiments, the first distribution structure 300 may include a plurality of redistribution insulation layers 310, which are stacked on each other. The first redistribution insulating layer 310 may be formed by using, for example, photo imageable dielectric (PID) material or photosensitive polyimide (PSPI) material. For example, the first distribution structure 300 may have a thickness of about 30 μm to about 50 μm.

The plurality of first redistribution patterns 330 may include a plurality of first redistribution line patterns 332 and a plurality of first redistribution vias 334. The plurality of first redistribution patterns 330 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or a combination thereof, but are not limited thereto. In some embodiments, the plurality of first redistribution patterns 330 may be formed by stacking a metal or an alloy (a combination of one or more metals) of a metal on a seed layer including Cu, Ti, titanium nitride, or titanium tungsten.

The plurality of first redistribution line patterns 332 may be disposed on an upper surface of the first redistribution insulating layer 310 and a lower surface of another first redistribution insulating layer 310. For example, when the first distribution structure 300 includes a plurality of first redistribution insulating layers 310, which are stacked on each other, the plurality of first redistribution line patterns 332 may be disposed on an upper surface of the first redistribution insulating layer 310 of the uppermost layer, on a lower surface of the first redistribution insulating layer 310 of the lowermost layer, and on at least a portion between two adjacent first redistribution insulating layers 310 among the plurality of first redistribution insulating layers 310.

The plurality of first redistribution vias 334 may penetrate at least one first redistribution insulating layer 310, and may be in contact with and connected to some of the plurality of first redistribution line patterns 332. For example, the plurality of first redistribution vias 334 may connect the first redistribution line patterns 332 disposed on a first redistribution insulating layer 310 to the first redistribution line patterns 332 disposed on an adjacent first redistribution insulating layer 310. In some embodiments, the plurality of first redistribution vias 334 may have a tapered shape that widens and extends horizontally from the bottom to the top thereof. For example, the plurality of first redistribution vias 334 may have an increasing horizontal width toward at least one semiconductor chip 100.

In some embodiments, at least some of the plurality of first redistribution line patterns 332 may be formed together with some of the plurality of first redistribution vias 334. For example, the first redistribution line pattern 332 and the first redistribution via 334 in contact with a lower surface of the first redistribution line pattern 332 may be formed together. For example, each of the plurality of first redistribution vias 334 may have a decreasing horizontal width away from the first redistribution line pattern 332, which is integrated therewith.

Among the plurality of first redistribution patterns 330, some that are disposed adjacent to a lower surface of the first distribution structure 300 may be referred to as a plurality of first lower surface connection pads 330P1. Similarly, some that are disposed adjacent to an upper surface of the first distribution structure 300 may be referred to as a plurality of first upper surface connection pads 330P2. For example, the plurality of first lower surface connection pads 330P1 may be some of the plurality of first redistribution line patterns 332 adjacent to the lower surface of the first distribution structure 300, and the plurality of first upper surface connection pads 330P2 may be some of the plurality of first redistribution line patterns 332 adjacent to the upper surface of the first distribution structure 300. For example, a bottom surface of the plurality of first lower surface connection pads 330P1 may be coplanar with a bottom surface of lowermost layer of the plurality of first redistribution insulating layer 310 or a bottom surface of the first distribution structure 300. A bottom surface of the plurality of first upper surface connection pads 330P2 may be disposed on an upper surface of uppermost layer of the plurality of first redistribution insulating layer 310 or an upper surface of the first distribution structure 300.

A plurality of external connection terminals 500 may be respectively connected to the plurality of first lower surface connection pads 330P1. The plurality of external connection terminals 500 may electrically connect the semiconductor package 1 to other electronic components or devices. In some embodiments, each of the plurality of external connection terminals 500 may include a bump, a solder ball, etc. For example, the external connection terminal 500 may have a height of about 100 μm to about 180 μm.

A plurality of chip connection members 130 may be connected to some of the plurality of first upper surface connection pads 330P2. A plurality of connection structures 200 may be connected to the remaining ones of the plurality of first upper surface connection pads 330P2. For example, plurality of chip connection members 130 may be disposed on an upper surface of some of the plurality of first upper surface connection pads 330P2. Similarly, plurality of connection structures 200 may be disposed on an upper surface of the remaining ones of the plurality of first upper surface connection pads 330P2.

The plurality of first upper surface connection pads 330P2 may be disposed on the upper surface of the first redistribution insulating layer 310. For example, when the first distribution structure 300 includes a plurality of first redistribution insulating layers 310, which are stacked on each other, the plurality of first upper surface connection pads 330P2 may be disposed on the upper surface of an uppermost first redistribution insulating layer 310.

At least one semiconductor chip 100 may be disposed on the first distribution structure 300. The semiconductor chip 100 may include a semiconductor substrate 110 having an active surface and an inactive surface thereof, which are opposite to each other, a semiconductor device 112 formed on the active surface of the semiconductor substrate 110, and a plurality of chip pads 120 disposed on a first surface of the semiconductor chip 100. For example, the plurality of chip pads 120 may be disposed on a lower surface of the semiconductor chip 100. For example, the semiconductor chip 100 may have a thickness of about 70 μm to about 200 μm. According to the present inventive concept, the first surface of the semiconductor chip 100 and a second surface of the semiconductor chip 100 may be opposite to each other, where the second surface of the semiconductor chip 100 may include the inactive surface of the semiconductor substrate 110. Because the active surface of the semiconductor substrate 110 is adjacent to the first surface of the semiconductor chip 100, an illustration of separating the active surface of the semiconductor substrate 110 from the first surface (or lower surface) of the semiconductor chip 100 is omitted.

In some embodiments, the semiconductor chip 100 may have a face-down arrangement, in which the first surface thereof is toward the first distribution structure 300, and may be attached to the upper surface of the first distribution structure 300. For example, the first surface of the semiconductor chip 100 may be referred to as a lower surface of the semiconductor chip 100, and the second surface of the semiconductor chip 100 may be referred to as an upper surface of the semiconductor chip 100. According to the present inventive concept, an upper surface is referred to a surface facing an upper side in the drawing, and a lower surface is referred to a surface facing a lower side in the drawing.

The plurality of chip connection members 130 may be disposed between the plurality of chip pads 120 of the semiconductor chip 100 and some of the plurality of first upper surface connection pads 330P2 of the first distribution structure 300. For example, each of the plurality of chip connection members 130 may include a solder ball or a micro-bump. The semiconductor chip 100 may be electrically connected to the first redistribution pattern 330 of the first distribution structure 300 via the plurality of chip connection members 130. Each of the plurality of chip connection members 130 may include a under bump metal (UBM) layer 132 and a conductive cap 134 covering the UBM layer 132, which are disposed under each of the plurality of chip pads 120. For example, the UBM layer 132 may be disposed between the chip pad 120 of the semiconductor chip 100 and the conductive cap 134 of the chip connection member 130. In some cases, the conductive cap 134 of the chip connection member 130 may be disposed on and electrically connected to an upper surface of some of the plurality of first upper surface connection pads 330P2. For example, each of the plurality of chip connection members 130 may have a height of about 30 μm to about 40 μm. Each of the plurality of chip connection members 130 may include a conductive material, for example, Cu, Al, silver (Ag), Sn, gold (Au), or solder, but is not limited thereto.

The semiconductor substrate 110 may include, for example, a semiconductor material, such as silicon (Si) and/or germanium (Ge). Alternatively, the semiconductor substrate 110 may include a compound semiconductor material, such as silicon carbide (SiC), gallium arsenide (GaAs), indium arsenide (InAs), and/or indium phosphate (InP). The semiconductor substrate 110 may include a conductive region, for example, a well doped with impurities. The semiconductor substrate 110 may have various element isolation structures, such as a shallow trench isolation (STI) structure.

The semiconductor substrate 110 may include the semiconductor device 112, including a plurality of individual devices of various types, on the active surface of the semiconductor substrate 110. The plurality of individual devices may include various microelectronic devices, for example, a metal-oxide-semiconductor field effect transistor (MOSFET), a complementary metal-insulator-semiconductor (CMOS) transistor, a system large scale integration (LSI), an active device, a passive device, etc. The plurality of individual devices may be electrically connected to the conductive region of the semiconductor substrate 110. The semiconductor device 112 may further include a conductive distribution or a conductive plug electrically connecting at least two of the plurality of individual devices to each other, or electrically connecting the plurality of individual devices to the conductive region of the semiconductor substrate 110. In addition, each of the plurality of individual devices may be electrically isolated from an adjacent individual device by an insulating layer.

In some embodiments, the semiconductor chip 100 may include a logic device. For example, the semiconductor chip 100 may include a central processing unit (CPU) chip, a graphics processing unit (GPU) chip, or an application processor (AP) chip. In some embodiments, when the semiconductor package 1 includes a plurality of semiconductor chips 100, at least one of the plurality of semiconductor chips 100 may include a CPU chip, a GPU chip, or an AP chip, and at least one semiconductor chip 100 may include a memory semiconductor chip including a memory device. For example, the memory device may include, for example, a non-volatile memory device, such as a flash memory, phase change random access memory (RAM) (PRAM), magnetic RAM (MRAM), ferroelectric RAM (FeRAM), and resistive RAM (RRAM). The flash memory may include, for example, a NAND flash memory or a V-NAND flash memory. In some embodiments, the memory device may include a volatile memory device, such as dynamic RAM (DRAM) and static RAM (SRAM).

The second distribution structure 400 may include a plurality of second redistribution insulating layers 410 and a plurality of second redistribution patterns 430. The plurality of second redistribution insulating layers 410 may surround the plurality of second redistribution patterns 430. For example, the plurality of second redistribution patterns 430 may be disposed between each of the second redistribution insulating layers 410, vertically and/or horizontally. The second redistribution insulating layer 410 may be formed from, for example, PID or PSPI material.

In some embodiments, the thickness of the second distribution structure 400 may be less than the thickness of the first distribution structure 300. For example, the second distribution structure 400 may have a thickness of about 20 μm to about 40 μm. In some embodiments, the second distribution structure 400 may include a plurality of second redistribution insulating layers 410, which are stacked on each other. The plurality of second redistribution patterns 430 may include a plurality of second redistribution line patterns 432 and a plurality of second redistribution vias 434. The plurality of second redistribution patterns 430 may include a metal or an alloy of metal, but are not limited thereto. In some embodiments, the plurality of second redistribution patterns 430 may be formed by stacking a metal or an alloy of a metal on a seed layer.

The plurality of second redistribution line patterns 432 may be disposed on an upper surface of the second redistribution insulating layer 410 and a lower surface of another second redistribution insulating layer 410. For example, when the second distribution structure 400 includes a plurality of second redistribution insulating layers 410, which are stacked on each other, the plurality of second redistribution line patterns 432 may be disposed on an upper surface of the second redistribution insulating layer 410 of the uppermost layer, on a lower surface of the second redistribution insulating layer 410 of the lowermost layer, and on at least a portion between two adjacent second redistribution insulating layers 410 among the plurality of second redistribution insulating layers 410.

Among the plurality of second redistribution patterns 430, some that are disposed adjacent to a lower surface of the second distribution structure 400 may be referred to as a plurality of second lower surface connection pads 430P1. Similarly, some that are disposed adjacent to an upper surface of the second distribution structure 400 may be referred to as a plurality of second upper surface connection pads 430P2. For example, the plurality of second lower surface connection pads 430P1 may be some that are disposed adjacent to the lower surface of the second distribution structure 400 among the plurality of second redistribution line patterns 432, and the plurality of second upper surface connection pads 430P2 may be some that are disposed adjacent to the upper surface of the second distribution structure 400 among the plurality of second redistribution line patterns 432. For example, a bottom surface of the plurality of second lower surface connection pads 430P1 may be coplanar with a bottom surface of lowermost layer of the plurality of second redistribution insulating layers 410 or a bottom surface of the second distribution structure 400. A bottom surface of the plurality of second upper surface connection pads 430P2 may be disposed on an upper surface of uppermost layer of the plurality of second redistribution insulating layers 410 or an upper surface of the second distribution structure 400.

In some other embodiments, the plurality of second lower surface connection pads 430P1 may include some of the plurality of second redistribution vias 434 disposed adjacent to the lower surface of the second distribution structure 400. For example, the plurality of second redistribution vias 434 may connect the second redistribution line patterns 432 disposed on a second redistribution insulating layer 410 to the second redistribution line patterns 432 disposed on an adjacent second redistribution insulating layer 410. second redistribution vias 434 may have substantially similar characteristics described with reference to the first redistribution vias 334.

In some embodiments, when the semiconductor package 1 includes a lower package of a PoP, an upper package thereof may be connected to a plurality of second upper surface connection pads 430P2. For example, a plurality of package connection terminals may be disposed between the upper package and the plurality of second upper surface connection pads 430P2. In some embodiments, each of the plurality of package connection terminals may include a bump, a solder ball, etc. The upper package may include an auxiliary semiconductor chip. The auxiliary semiconductor chip may include a memory semiconductor chip. For example, the auxiliary semiconductor chip may include a DRAM chip, an SRAM chip, a flash memory chip, an EEPROM chip, a PRAM chip, an MRAM chip, or an RRAM chip. The plurality of connection structure 200 may be respectively connected to the plurality of second lower surface connection pads 430P1. In an embodiment, some of the second lower surface connection pads 430P1 of the second distribution structure 400 may be connected to the corresponding first upper surface connection pads 330P2 of the first distribution structure 300 via the connection structures 200.

The plurality of second lower surface connection pads 430P1 may be disposed under the lower surface of the second redistribution insulating layer 410. For example, when the second distribution structure 400 includes a plurality of second redistribution insulating layers 410, which are stacked on each other, the plurality of second lower surface connection pads 430P1 may be disposed under the lower surface of the lowermost second redistribution insulating layer 410.

The plurality of second upper surface connection pads 430P2 may be disposed on the upper surface of the second redistribution insulating layer 410. For example, when the second distribution structure 400 includes the plurality of second redistribution insulating layers 410, which are stacked on each other, the plurality of second upper surface connection pads 430P2 may be arranged on the upper surface of the uppermost second redistribution insulating layer 410. The plurality of second upper surface connection pads 430P2 may protrude from the upper surface of the second redistribution insulating layer 410 in a vertical direction, that is, in a direction opposite to the semiconductor chip 100 and the first distribution structure 300. For example, when the second distribution structure 400 includes the plurality of second redistribution insulating layers 410, which are stacked on each other, the plurality of second upper surface connection pads 430P2 may protrude from the upper surface of the second redistribution insulating layer 410 at the uppermost layer in a vertical direction away from the semiconductor chip 100 and the first distribution structure 300. An upper surface and at least a portion of the side surfaces of each of the plurality of second upper surface connection pads 430P2 may not be in contact with the second redistribution insulating layer 410.

The plurality of second redistribution vias 434 may penetrate at least one second redistribution insulating layer 410, and may be respectively in contact with and connected to some of the plurality of second redistribution line patterns 432. In some embodiments, at least some of the plurality of second redistribution line patterns 432 may be formed together with some of the plurality of second redistribution vias 434. For example, the second redistribution line pattern 432 and the second redistribution via 434 in contact with the lower surface of the second redistribution line pattern 432 may be formed together.

In some embodiments, the plurality of second redistribution vias 434 may have a tapered shape that widens and extends horizontally from the bottom to the top thereof. For example, the plurality of second redistribution vias 434 may have a decreasing horizontal width toward at least one semiconductor chip 100. The plurality of first redistribution vias 334 and the plurality of second redistribution vias 434 may extend in the same direction, and may each have an increasing horizontal width or a decreasing horizontal width. For example, the plurality of first redistribution vias 334 and the plurality of second redistribution vias 434 may have tapered shapes which extend in a direction from the first distribution structure 300 toward the second distribution structure 400 and have increasing horizontal widths, or alternatively, extend in a direction from the second distribution structure 400 toward the first distribution structure 300 and have decreasing horizontal widths.

The first redistribution insulating layer 310 may be referred to as a first base insulating layer, the first redistribution pattern 330 may be referred to as a first distribution pattern, the first redistribution line pattern 332 may be referred to as a first distribution line pattern, and the first redistribution via 334 may be referred to as a first distribution via. The second redistribution insulating layer 410 may be referred to as a second base insulating layer, the second redistribution pattern 430 may be referred to as a second distribution pattern, the second redistribution line pattern 432 may be referred to as a second redistribution line pattern, and the second redistribution via 434 may be referred to as a second redistribution via.

An encapsulant 250 may surround at least one semiconductor chip 100 disposed on the upper surface of the first distribution structure 300. For example, the encapsulant 250 may cover at least a portion of side surfaces and an upper surface of the at least one semiconductor chip 100. The encapsulant 250 may fill a space between the first distribution structure 300 and the second distribution structure 400. For example, the encapsulant 250 may fill a space between adjacent connection structures 200. The encapsulant 250 may fill a space between connection structures 200 and the semiconductor chip 100. For example, the encapsulant 250 may have a thickness of about 150 μm to about 300 μm. The encapsulant 250 may include a polymer material. For example, the encapsulant 250 may include a molding member including an epoxy mold compound (EMC). The encapsulant 250 may include a filler. For example, the filler may include a ceramic-based material having non-conductive insulating properties. In some embodiments, the filler may include AlN, BN, Al₂O₃, SiC, and/or MgO. For example, the filler may include a silica filler or an alumina filler. For example, the encapsulant 250 may include an epoxy-based material containing the filler. An average diameter of the filler in the encapsulant 250 may be about 3 μm to about 50 μm. The ratio of the filler in the encapsulant 250 may be about 60 wt % to about 90 wt %.

In some embodiment, an under-fill layer 150 may be disposed between the semiconductor chip 100 and the first distribution structure 300. The under-fill layer 150 may surround the plurality of chip connection members 130. In some embodiments, the under-fill layer 150 may fill a space between at least one semiconductor chip 100 and the first distribution structure 300, and cover a portion of lower sides of side surfaces of at least one semiconductor chip 100. The under-fill layer 150 may include, for example, an epoxy resin formed by a capillary under-fill method. In some embodiment, the under-fill layer 150 may include a non-conductive film (NCF).

In some embodiments, at least one semiconductor chip 100 and the second distribution structure 400 may be apart from each other in the vertical direction. For example, the upper surface of at least one semiconductor chip 100 may be at a lower vertical level than a level of the lower surface of the second distribution structure 400. The encapsulant 250 may fill a space between at least one semiconductor chip 100 and the second distribution structure 400.

In some embodiments, side surfaces of the first distribution structure 300, side surfaces of the encapsulant 250, and side surfaces of the second distribution structure 400 may be aligned with each other in the vertical direction. For example, one side surface of the first distribution structure 300, one side surface of the encapsulant 250, and one side surface of the second distribution structure 400, may be coplanar with each other.

The plurality of connection structures 200 may penetrate the encapsulant 250, and electrically connect the first distribution structure 300 to the second distribution structure 400. The encapsulant 250 may surround sidewalls of the plurality of connection structures 200.

The plurality of connection structures 200 may be disposed between the first distribution structure 300 and the second distribution structure 400 so that the plurality of connection structures 200 are spaced apart from at least one semiconductor chip 100 in a horizontal direction. For example, the plurality of connection structures 200 may be apart from at least one semiconductor chip 100 in the horizontal direction, and disposed adjacent to at least one semiconductor chip 100. The plurality of connection structures 200 may be disposed between the plurality of first upper surface connection pads 330P2 and the plurality of second lower surface connection pads 430P1. Lower surfaces of the plurality of connection structures 200 may be in contact with the plurality of first upper surface connection pads 330P2 of the first distribution structure 300 and electrically connected to the plurality of first redistribution patterns 330. The upper surfaces of the plurality of connection structures 200 may be in contact with the plurality of second lower surface connection pads 430P1 and electrically connected to the plurality of second redistribution patterns 430. For example, the height of each of the plurality of connection structures 200 may be about 150 μm to about 300 μm, and a horizontal width of each of the plurality of connection structures 200 may be about 120 μm to about 200 μm. An aspect ratio of each of a plurality of connection structures 200, that is, a ratio of a height over a horizontal width, may be greater than about 1.

The lower surface of each of the plurality of connection structures 200 may be in contact with an upper surface of the first upper surface connection pad 330P2. The upper surface of each of the plurality of connection structures 200 may be in contact with a lower surface of the second lower surface connection pad 430P1. In some embodiments, a horizontal width and a horizontal area of the first upper surface connection pad 330P2 in contact with the connection structure 200 may be greater than a horizontal width and a horizontal area of the connection structure 200. In some embodiments, the horizontal width and a horizontal area of the second lower surface connection pad 430P1 in contact with the connection structure 200 may be greater than the horizontal width and the horizontal area of the connection structure 200. For example, the lower surface of the connection structure 200 may be entirely in contact with the upper surface of the first upper surface connection pad 330P2, but a portion of the upper surface of the first upper surface connection pad 330P2 may not be in contact with the plurality of connection structures 200. For example, the upper surface of the connection structure 200 may be entirely in contact with the lower surface of the second upper surface connection pad 430P1, but a portion of the lower surface of the second upper surface connection pad 430P1 may not be in contact with the plurality of connection structures 200. The portion of the first upper surface connection pad 330P2 that is not in contact with the plurality of connection structures 200 and the portion of the lower surface of the second upper surface connection pad 430P1 that is not in contact with the plurality of connection structures 200 may be covered by the encapsulant 250.

Each of the plurality of connection structures 200 may include a conductive post 220 and a conductive antioxidant layer 210 surrounding the conductive post 220. For example, the conductive antioxidant layer 210 may surround side surfaces and a bottom surface of the conductive post 220. The conductive post 220 may electrically connect the first distribution structure 300 to the second distribution structure 400. For example, a plurality of conductive posts 220 included in the plurality of connection structures 200 may electrically connect the first upper surface connection pad 330P2 and the second lower surface connection pad 430P1.

The conductive post 220 may extend in the vertical direction. The conductive post 220 may have a horizontal cross-section of a circular, elliptical, or polygonal shape, and have a pillar shape extending in the vertical direction. For example, the conductive post 220 may include copper (Cu) or a copper alloy. The conductive antioxidant layer 210 may cover one or more side surfaces of the conductive post 220. In some embodiments, the conductive antioxidant layer 210 may cover all side surfaces of the conductive post 220. The conductive antioxidant layer 210 may cover a lower surface of the conductive post 220 but might not cover an upper surface of the conductive post 220. For example, the conductive antioxidant layer 210 may have a cylindrical shell shape with an open top and a closed bottom, and the conductive post 220 may have a circular pillar shape filling the inside of the cylindrical shell shape with an open top and a closed bottom.

An upper surface of the conductive post 220 and the uppermost end of the conductive antioxidant layer 210 may be in contact with the second lower surface connection pad 430P1. The lower surface of the second lower surface connection pad 430P1 may cover both the upper surface of the conductive post 220 and the uppermost end (or surface) of the conductive antioxidant layer 210. The lower surface of the conductive post 220 may be in contact with the conductive antioxidant layer 210. The conductive antioxidant layer 210 may cover the lower surfaces of the conductive post 220. The lower surface of the conductive antioxidant layer 210 may be in contact with the first upper surface connection pad 330P2. The upper surface of the first upper surface connection pad 330P2 may cover the lower surfaces of the conductive antioxidant layer 210. The conductive post 220 may be in contact with the second lower surface connection pad 430P1, but may not be in contact with the first upper surface connection pad 330P2. The conductive posts 220 may include the conductive antioxidant layer 210 therebetween, and may be apart from the first upper surface connection pad 330P2. For example, the lower surface of the conductive antioxidant layer 210 is disposed between the conductive posts 220 and the first upper surface connection pad 330P2. The conductive antioxidant layer 210 may be disposed in a space between the conductive post 220 and the encapsulant 250, and in a space between the conductive post 220 and the first upper surface connection pad 330P2, and may extend along the spaces. The conductive antioxidant layer 210 may conformally cover the side surfaces and the lower surface of the conductive post 220.

The conductive antioxidant layer 210 may be in contact with the encapsulant 250, but the conductive post 220 might not be in contact with the encapsulant 250. The conductive antioxidant layer 210 may be disposed between the conductive post 220 and the encapsulant 250. The conductive post 220 and the encapsulant 250 may include the conductive antioxidant layer 210 therebetween, and may be apart from each other.

The conductive antioxidant layer 210 may include a material including a metal atom. For example, the conductive antioxidant layer 210 may include a metal, an alloy, or a conductive metal nitride. For example, the conductive antioxidant layer 210 may include Ti, Ta, TiN, or TaN. In some embodiments, the conductive antioxidant layer 210 may include a metal atom included by the conductive post 220 and an alloy including another metal atom. For example, when the conductive post 220 includes Cu or copper alloy, the conductive antioxidant layer 210 may include an alloy including a metal, such as titanium (Ti), palladium (Pd), chromium (Cr), and aluminum (Al), and/or Cu. For example, the thickness TK of the conductive antioxidant layer 210 may be about 10 nm to about 1 μm.

The plurality of first upper surface connection pads 330P2 may protrude from the upper surface of the uppermost first redistribution insulating layer 310 in the vertical direction toward the semiconductor chip 100 and the second distribution structure 400. For example, when the first distribution structure 300 includes the plurality of first redistribution insulating layers 310, which are stacked on each other, the plurality of first upper surface connection pads 330P2 may protrude from the upper surface of the first redistribution insulating layer 310 at the uppermost layer in the vertical direction toward the semiconductor chip 100 and the second distribution structure 400. The upper surface and at least a portion of the side surfaces of each of the plurality of first upper surface connection pads 330P2 may not be in contact with the first redistribution insulating layer 310. The encapsulant 250 may cover at least a portion of the side surfaces and a portion of the upper surface of each of the plurality of first upper surface connection pads 330P2. The remaining portion of the upper surface of each of the plurality of first upper surface connection pads 330P2 may cover and in contact with the conductive antioxidant layer 210. The plurality of first lower surface connection pads 330P1 may not protrude in the vertical direction from the lower surface of the first redistribution insulating layer 310 at the lowermost layer. In some embodiments, the lower surface of the plurality of first lower surface connection pads 330P1, the lower surface of the first redistribution insulating layer 310 at the lowermost layer, and the lower surface of the first distribution structure 300 may be coplanar with each other.

The plurality of second lower surface connection pads 430P1 may not protrude in the vertical direction from the lower surface of the second redistribution insulating layer 410 at the lowermost layer. The second redistribution insulating layer 410 may cover side surfaces of each of the plurality of second lower surface connection pads 430P1. In some embodiments, the lower surface of the plurality of second lower surface connection pads 430P1, the lower surface of the second redistribution insulating layer 410 at the lowermost layer, and the lower surface of the second distribution structure 400 may be coplanar with each other.

The encapsulant 250 may cover a portion of the lower surface of each of the plurality of second lower surface connection pads 430P1. The remaining portion of the lower surface of each of the plurality of second lower surface connection pads 430P1 may cover and in contact with the uppermost end (or surface) of the conductive antioxidant layer 210 and the upper surface of the conductive post 220. The encapsulant 250 may be in contact with a portion of the lower surface of each of the plurality of second lower surface connection pads 430P1, and the lower surface of the second redistribution insulating layer 410 at the lowermost layer. The upper surface of the encapsulant 250, the uppermost end of the conductive antioxidant layer 210, the upper surface of the conductive post 220, the lower surface of the second distribution structure 400, lower surface of the second redistribution insulating layer 410 at the lowermost layer, and the lower surface of each of the plurality of second lower surface connection pads 430P1 may be disposed on a same level and coplanar with each other.

The semiconductor package 1 according to the present inventive concept may include the conductive antioxidant layer 210 covering the surface of the conductive post 220 which electrically connects the first distribution structure 300 and the second distribution structure 400. The conductive antioxidant layer 210 may prevent the generation of an oxide layer on the surface of the conductive post 220. When an oxide layer is formed on the surface of the conductive post 220, metal atoms included in the conductive post 220 may move to the oxide layer, micro voids may occur between the conductive post 220 and the oxide layer, and delamination may occur at the interface between the conductive post 220 and the oxide layer due to the micro voids. However, the semiconductor package 1 according to the present inventive concept may prevent the oxide layer from forming on the surface of the conductive post 220 by covering the surface of the conductive post 220 by using the conductive antioxidant layer 210. Accordingly, the micro voids due to the formation of oxide layer may be avoided, and the reliability of the semiconductor package 1 may be improved.

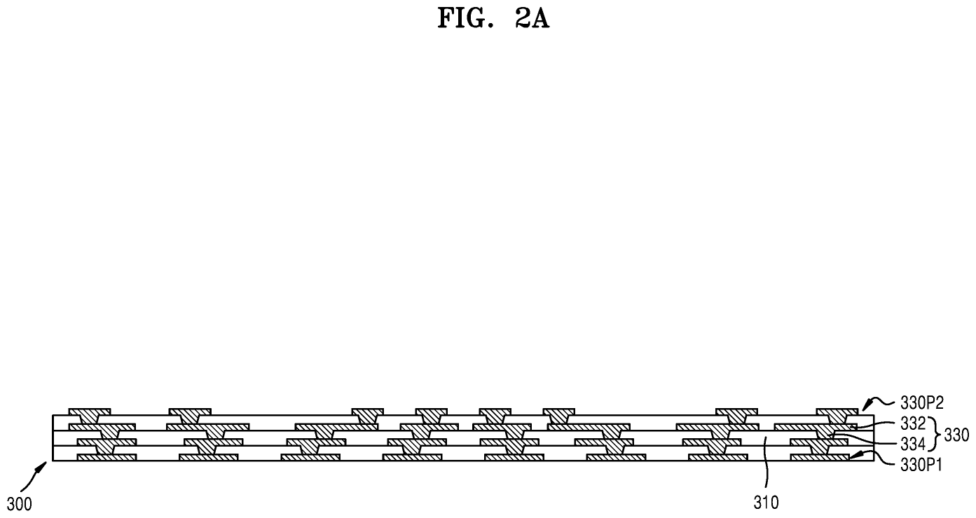

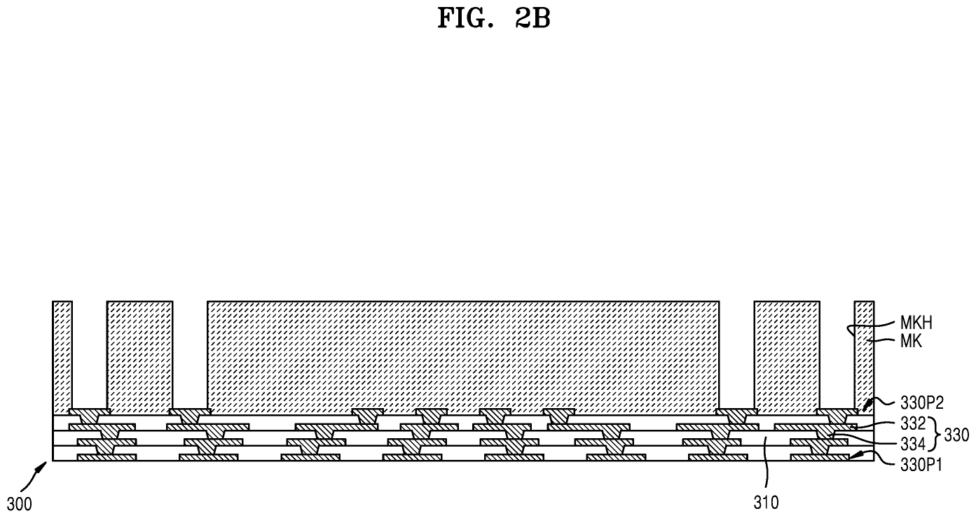

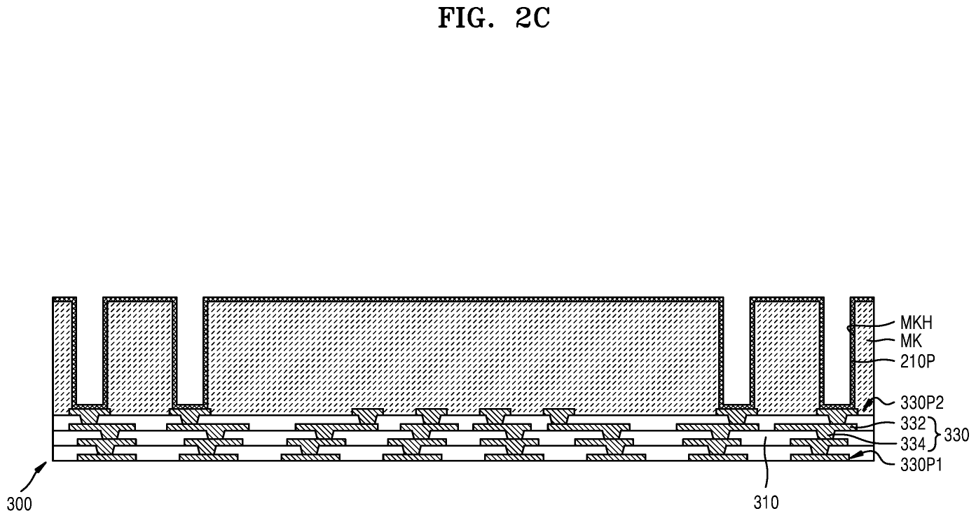

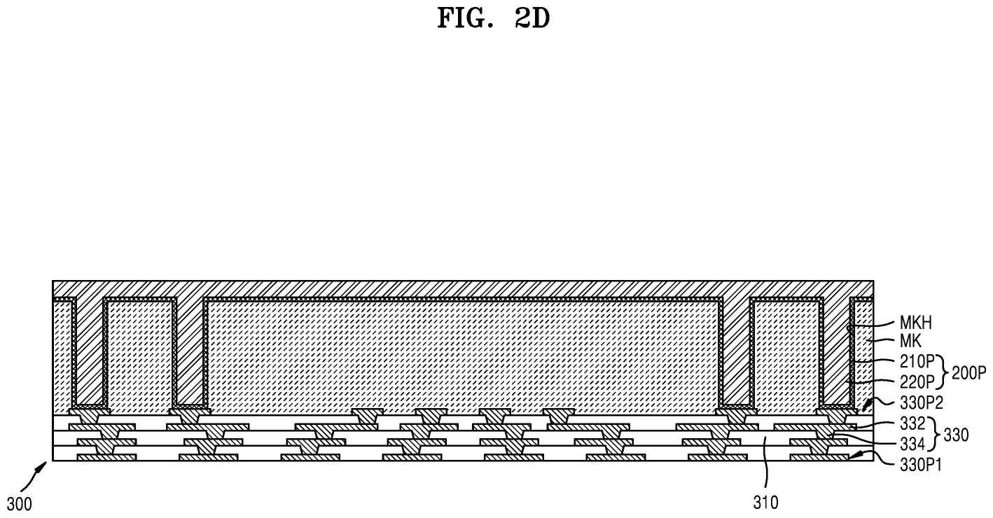

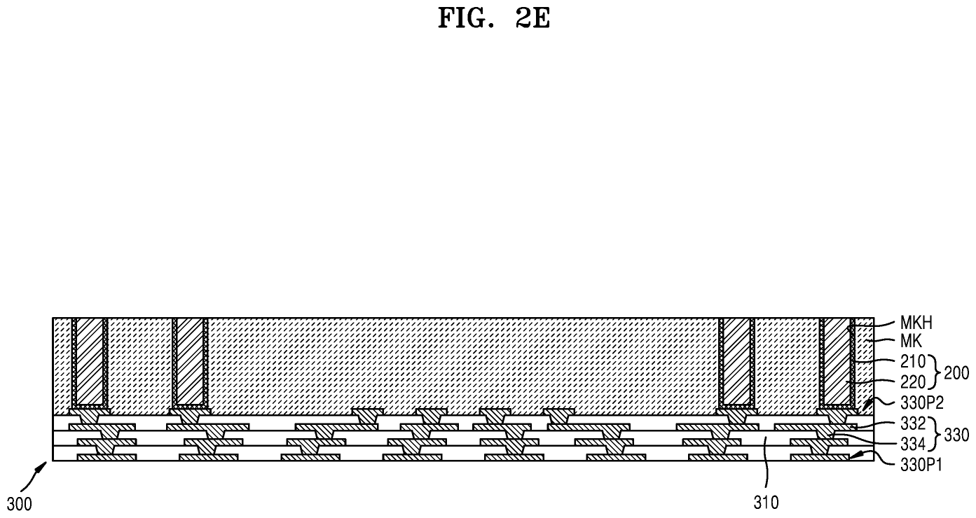

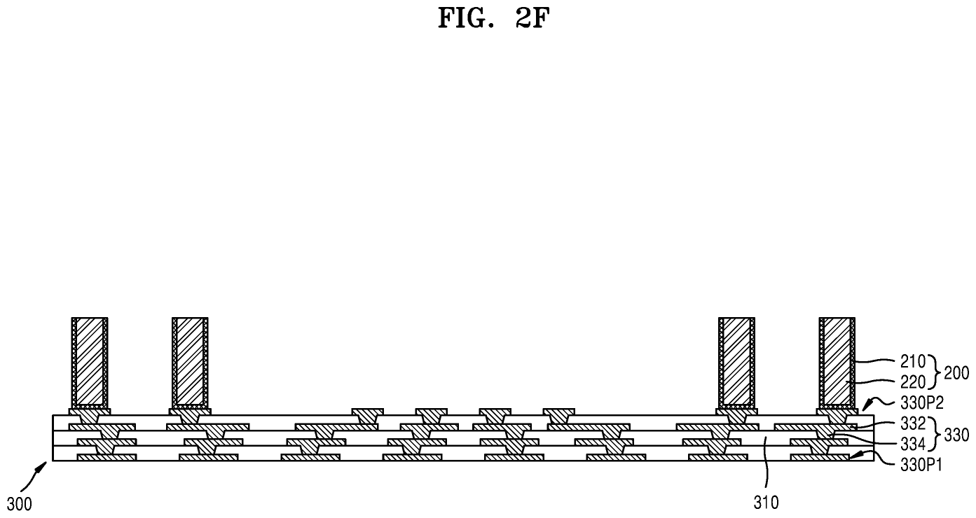

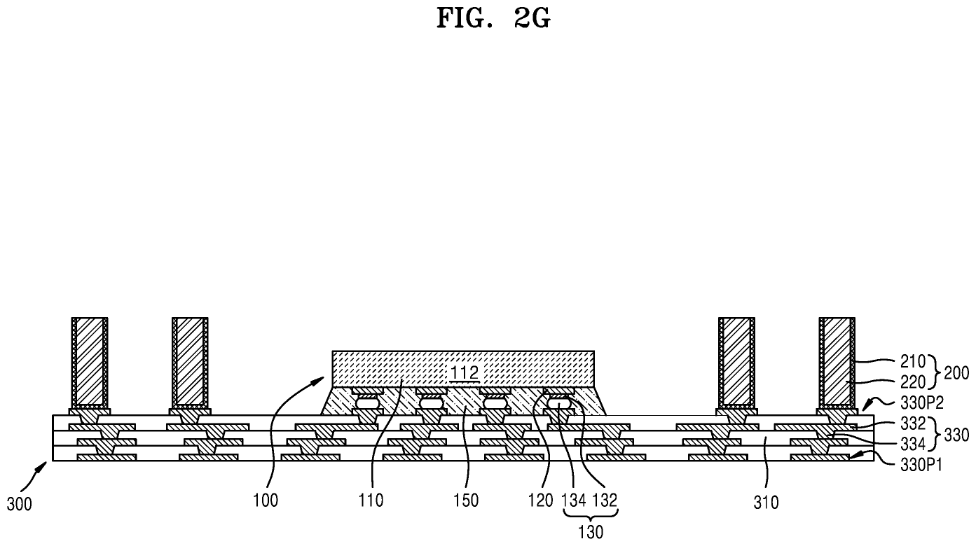

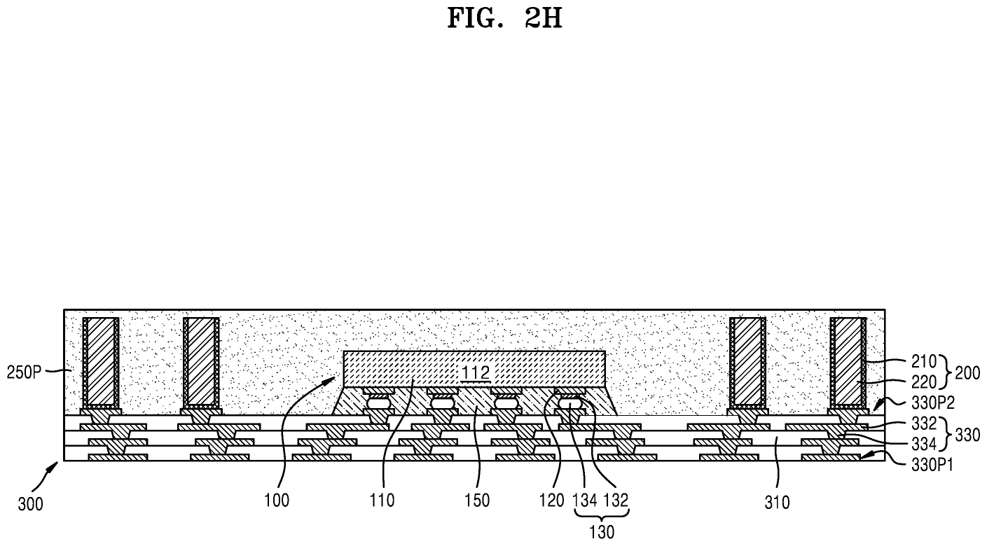

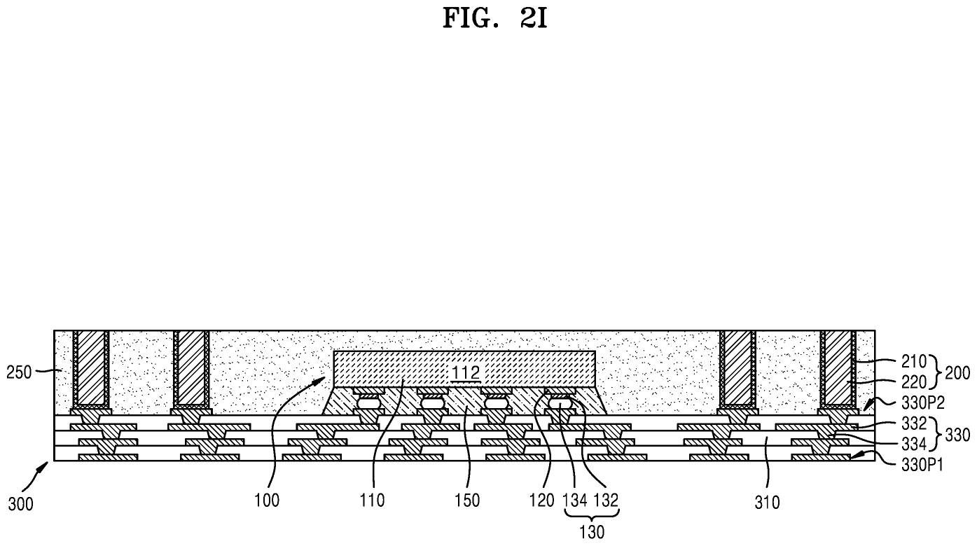

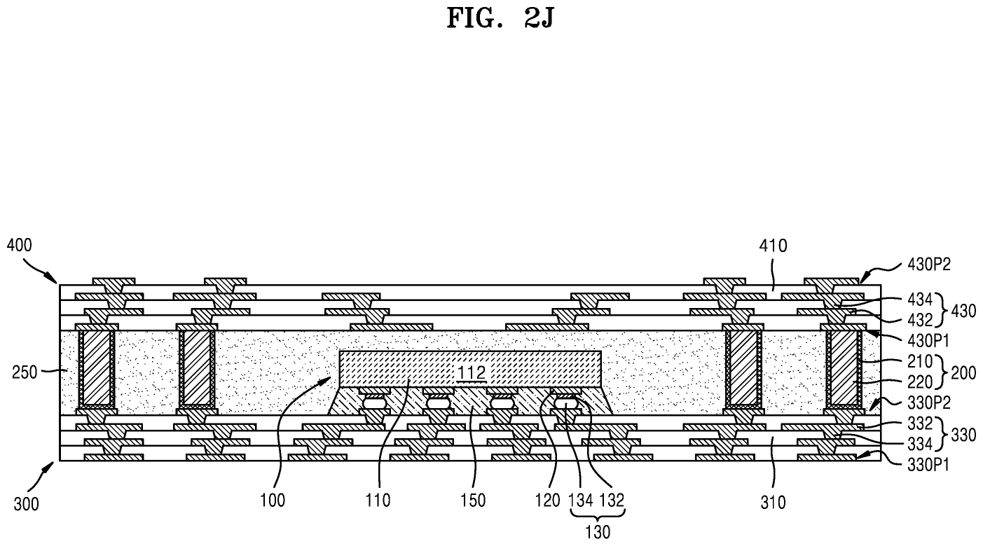

FIGS. 2A through 2J are cross-sectional views illustrating a method of manufacturing a semiconductor package, according to embodiments of the present inventive concept; FIGS. 2A through 2J are cross-sectional views illustrating a method of manufacturing the semiconductor package 1 illustrated in FIG. 1, and omitted details are understood to be the same as described for corresponding elements elsewhere in the disclosure.

Referring to FIG. 2A, the first distribution structure 300 including the first redistribution insulating layer 310 and the plurality of first redistribution patterns 330 may be provided on a support substrate. The plurality of first redistribution patterns 330 includes a plurality of first redistribution line patterns 332 and a plurality of first redistribution vias 334. The support substrate may include a semiconductor substrate, a glass substrate, a ceramic substrate, or a plastic substrate. In some embodiments, after a release film is attached to the support substrate, the first distribution structure 300 may be formed.

The first redistribution line patterns 332 may be formed on the support substrate. The first redistribution line patterns 332 formed on the support substrate may include a plurality of first lower surface connection pads 330P1. Then, a first preliminary redistribution insulating layer covering the first redistribution line patterns 332 (or the plurality of first lower surface connection pads 330P1) on the support substrate is formed. A portion of the first preliminary redistribution insulating layer may be removed by performing an exposure process and a development process on the first preliminary redistribution insulating layer, the first redistribution insulating layer 310 including a plurality of first via holes may be formed. For example, the plurality of first via holes may be used to form the first redistribution vias 334. The plurality of first via holes may be formed such that a horizontal width thereof decreases from an upper surface to a lower surface of the first redistribution insulating layer 310. In some embodiments, the lower surface of the plurality of first lower surface connection pads 330P1 and the lower surface of the first redistribution insulating layer 310 at the lowermost layer may be disposed at a same level and coplanar with each other.

After a first redistribution conductive layer is formed on the first redistribution insulating layer 310, the first redistribution conductive layer may be patterned, and the first redistribution patterns 330 including first redistribution line patterns 332 and the first redistribution vias 334 may be formed. The first redistribution vias 334 may include portions respectively filling the plurality of first via holes among the first redistribution patterns 330, and the first redistribution line patterns 332 may include portions above the upper surface of the first redistribution insulating layer 310 among the first redistribution patterns 330.

The first redistribution vias 334 may be formed such that a horizontal width thereof decreases from the upper surface to the lower surface of the first redistribution insulating layer 310. Because the first redistribution patterns 330 including the first redistribution line patterns 332 and the first redistribution vias 334 are formed by patterning the first redistribution conductive layer, at least some of the first redistribution line patterns 332, formed on the first redistribution insulating layer 310 including the plurality of first via holes, may be formed with at least some of the first redistribution vias 334.

Thereafter, the first redistribution insulating layer 310 and the first redistribution patterns 330 may be repeatedly formed, to form the first distribution structure 300. For example, the first redistribution insulating layer 310 and the first redistribution patterns 330 may be repeatedly formed such that the additional first redistribution vias 334 are disposed on the upper surface of the corresponding first redistribution line patterns 332 so that the first redistribution patterns 330 may be electrically connected to the first redistribution patterns 330 in a different layer. The first redistribution line patterns 332 formed on the upper surface of the first distribution structure 300 may include a plurality of first upper surface connection pads 330P2. In some embodiments, the plurality of first upper surface connection pads 330P2 may be formed to protrude from the upper surface of the first redistribution insulating layer 310 at the uppermost layer. In some embodiments, when the first distribution structure 300 is formed to include a plurality of first redistribution insulating layers 310, which are stacked on each other, the plurality of first upper surface connection pads 330P2 may be formed on the upper surface of the first redistribution insulating layer 310 at the uppermost layer.

Referring to FIG. 2B, a mask pattern MK having a plurality of mask holes MKH may be formed on the first distribution structure 300 to cover the plurality of first redistribution insulating layers 310 and the plurality of first upper surface connection pads 330P2. For example, the mask pattern MK may include photoresist. The plurality of mask holes MKH may be formed in accordance to some of the plurality of first upper surface connection pads 330P2. The plurality of mask holes MKH may penetrate the mask pattern MK. A portion of the upper surface of the first upper surface connection pad 330P2 may be exposed via the plurality of mask holes MKH. The plurality of mask holes MKH may be used to form the plurality of connection structures 200 illustrated in FIG. 1.

Referring to FIG. 2C, a conductive antioxidant layer 210P of connection structures 200P may be formed on the first distribution structure 300 in which the mask pattern MK is formed. The conductive antioxidant layer 210P may cover an upper surface of the mask pattern MK, and inner side surfaces and a lower surface of each of the plurality of mask holes MKH. For example, the conductive antioxidant layer 210P may conformally cover the upper surface of the mask pattern MK, the side surfaces of the mask pattern MK exposed at the inner surface of each of the plurality of mask holes MKH, and the upper surface of the first upper surface connection pad 330P2 exposed via the plurality of mask holes MKH. The conductive antioxidant layer 210P may include a material, which is capable of preventing oxidation of the surface of a conductive filling material layer (220P in FIG. 2D), to be described below. For example, the conductive antioxidant layer 210P may include a metal, a conductive metal nitride, or a copper alloy, but is not limited thereto. The conductive antioxidant layer 210P may be formed to have a thickness of, for example, about 10 nm to about 1 μm.

Referring to FIG. 2D, the conductive filling material layer 220P covering the conductive antioxidant layer 210P and filling the plurality of mask holes MKH may be formed. The conductive filling material layer 220P may be formed to fill all of the plurality of mask holes MKH. The conductive filling material layer 220P may include, for example, Cu or a copper alloy.

Referring to FIGS. 2D and 2E, the plurality of connection structures 200, including the conductive post 220 and the conductive antioxidant layer 210 surrounding the conductive post 220, may be formed by removing a portion of the upper surface of the conductive filling material layer 220P and a portion of the upper surface of the conductive antioxidant layer 210P to expose the mask pattern MK. For example, the upper surface of the mask pattern MK, the upper surface of the conductive antioxidant layer 210P, and upper surface of the conductive filling material layer 220P may be exposed. Accordingly, the conductive antioxidant layer 210P may become the conductive antioxidant layer 210, the conductive filling material layer 220P may become the conductive post 220.

The conductive antioxidant layer 210 may be disposed in a space between the conductive post 220 and the mask pattern MK, and in a space between the conductive post 220 and the first upper surface connection pad 330P2, and may extend along the spaces.

The plurality of connection structures 200 may be formed by removing a portion of the conductive filling material layer 220P and a portion of the conductive antioxidant layer 210P using a CMP process. The plurality of connection structures 200 may respectively fill the plurality of mask holes MKH. In the process of forming the plurality of connection structures 200, a portion of the upper surface of the mask pattern MK may be removed.

Referring to FIGS. 2E and 2F, the mask pattern MK may be removed from the first distribution structure 300. In some embodiments, after the mask pattern MK is removed therefrom, a bake process for removing moisture from the first distribution structure 300 and the plurality of connection structures 200 may be performed. Additionally or alternatively, plasma treatment for particle removal and surface treatment may be performed. In a bake process and/or a plasma process, because the side surfaces of the conductive post 220 are covered by the conductive antioxidant layer 210, a portion of the side surfaces of the conductive post 220 may not be oxidized. In some cases, in a bake process and/or a plasma process, oxidation may occur on a portion of the upper surface of the conductive post 220 which is not covered by the conductive antioxidant layer 210.

Referring to FIG. 2G, at least one semiconductor chip 100 including the plurality of chip pads 120 may be disposed on the first distribution structure 300. The semiconductor chip 100 may be disposed on the first distribution structure 300 so that the plurality of chip connection members 130 are disposed between the plurality of chip pads 120 and some of the plurality of first upper surface connection pads 330P2 of the first distribution structure 300. The semiconductor chip 100 may be disposed on the first distribution structure 300 and spaced apart from the plurality of connection structures 200 in the horizontal direction. In some embodiments, each of the plurality of chip connection members 130, including the UBM layer 132 and the conductive cap 134 covering the UBM layer 132, is formed on the plurality of chip pads 120 of at least one semiconductor chip 100. The at least one semiconductor chip 100, in which the plurality of chip connection members 130 are formed, may be electrically connected to the first distribution structure 300. For example, the plurality of chip pads 120 of at least one semiconductor chip 100 may be disposed on the UBM layer 132 of the plurality of chip connection members 130. The UBM layer 132 of the plurality of chip connection members 130 may be disposed between the plurality of chip pads 120 of at least one semiconductor chip 100 and the conductive cap 134, which is disposed on the plurality of first upper surface connection pads 330P2 of the first distribution structure 300.

In some embodiments, the under-fill layer 150 may be formed to fill a region between at least one semiconductor chip 100 and the first distribution structure 300. The under-fill layer 150 may be formed to surround the plurality of chip connection members 130. For example, the under-fill layer 150 may be formed to fill a region between at least one semiconductor chip 100 and the first distribution structure 300, and to cover portions of lower sides of side surfaces of at least one semiconductor chip 100.

In some embodiments, after at least one semiconductor chip 100 is attached to the first distribution structure 300, a bake process for removing moisture from the first distribution structure 300, the plurality of connection structures 200, and at least one semiconductor chip 100, and/or a plasma treatment for particle removal and surface treatment may be performed.

Referring to FIG. 2H, a preliminary encapsulant 250P, covering at least one semiconductor chip 100 and the plurality of connection structures 200, may be formed on the first distribution structure 300. To cover the upper surfaces of each of the plurality of connection structures 200, the preliminary encapsulant 250P may be formed to have an upper surface at a vertical level higher than a level of the upper surfaces of the plurality of connection structures 200. The preliminary encapsulant 250P may include a molding member including an EMC.

Referring to FIGS. 2H and 2I, the encapsulant 250 may be formed by removing a portion of the upper surface of a preliminary encapsulant 250P to expose the plurality of connection structures 200. The encapsulant 250 may be formed by removing a portion of the preliminary encapsulant 250P using a CMP process.

In some embodiments, in the process of forming the encapsulant 250, portions of the upper surfaces of the plurality of connection structures 200 may be removed. When an oxide layer is formed by oxidation on a portion of the upper surface of the conductive post 220, which is not covered by the conductive antioxidant layer 210, the oxide layer generated on the upper surface of the conductive post 220 may be removed in the process of removing portions of the upper surfaces of the preliminary encapsulant 250P and the plurality of connection structures 200.

Referring to FIG. 2J, the second distribution structure 400 including the second redistribution insulating layer 410 and the plurality of second redistribution patterns 430 may be formed on the plurality of connection structures 200 and the encapsulant 250. The plurality of second redistribution patterns 430 may include a plurality of second redistribution line patterns 432 and a plurality of second redistribution vias 434. The method of forming the second distribution structure 400 may be substantially to the method of forming the first distribution structure 300.

After a second preliminary redistribution insulating layer is formed on the plurality of connection structures 200 and the encapsulant 250, portions of the second preliminary redistribution insulating layer may be removed by performing an exposure process and a development process. As a result, the second redistribution insulating layer 410 including a plurality of second via holes may be formed. The plurality of second via holes may be formed such that a horizontal width thereof decreases from an upper surface to a lower surface of the second redistribution insulating layer 410. After a second redistribution conductive layer is formed on the second redistribution insulating layer 410, by patterning the second redistribution conductive layer, the second redistribution patterns 430 including the second redistribution line patterns 432 and the second redistribution vias 434 may be formed. The second redistribution patterns 430 formed on the plurality of connection structures 200 may include the plurality of second lower surface connection pads 430P1. The second redistribution vias 434 may include portions filling the plurality of second via holes among the second redistribution patterns 430, and the second redistribution line patterns 432 may include portions above the upper surface of the second redistribution insulating layer 410 among the second redistribution patterns 430. The second redistribution vias 434 may be formed such that a horizontal width thereof decreases from the upper surface to the lower surface of the second redistribution insulating layer 410. For example, the second redistribution vias 434 may have a shape substantially similar to the shape of the plurality of second via holes. Because the second redistribution patterns 430, including the second redistribution line patterns 432 and the second redistribution vias 434, are formed by patterning the second redistribution conductive layer, at least some of the second redistribution line patterns 432 formed on the second redistribution insulating layer 410 including the plurality of second via holes may be formed with at least some of the second redistribution vias 434.

Thereafter, the second redistribution insulating layer 410 and the second redistribution patterns 430 may be repeatedly formed, to form the second distribution structure 400. For example, the second redistribution insulating layer 410 and the second redistribution patterns 430 may be repeatedly formed such that the additional second redistribution vias 434 are disposed on the upper surface of the corresponding second redistribution line patterns 432 so that the second redistribution patterns 430 may be electrically connected to the second redistribution patterns 430 in a different layer. In some embodiments, the lower surface of the plurality of second lower surface connection pads 430P1 and the lower surface of the second redistribution insulating layer 410 at the lowermost layer may be coplanar with each other. In some embodiments, the plurality of second upper surface connection pads 430P2 may be formed to protrude from the upper surface of the second redistribution insulating layer 410 at the uppermost layer.

Accordingly, as illustrated in FIG. 1, by disposing the plurality of external connection terminals 500 to the plurality of first lower surface connection pads 330P1 of the first distribution structure 300, the semiconductor package 1 may be formed.

Referring to FIGS. 1 through 2J, the semiconductor package 1 according to the present inventive concept may include the conductive antioxidant layer 210 surrounding the conductive post 220. Accordingly, because a portion of the side surfaces of the conductive post 220 is oxidized to prevent an oxide layer from being formed on the side surfaces of the conductive post 220, the reliability of the semiconductor package 1 may be improved.

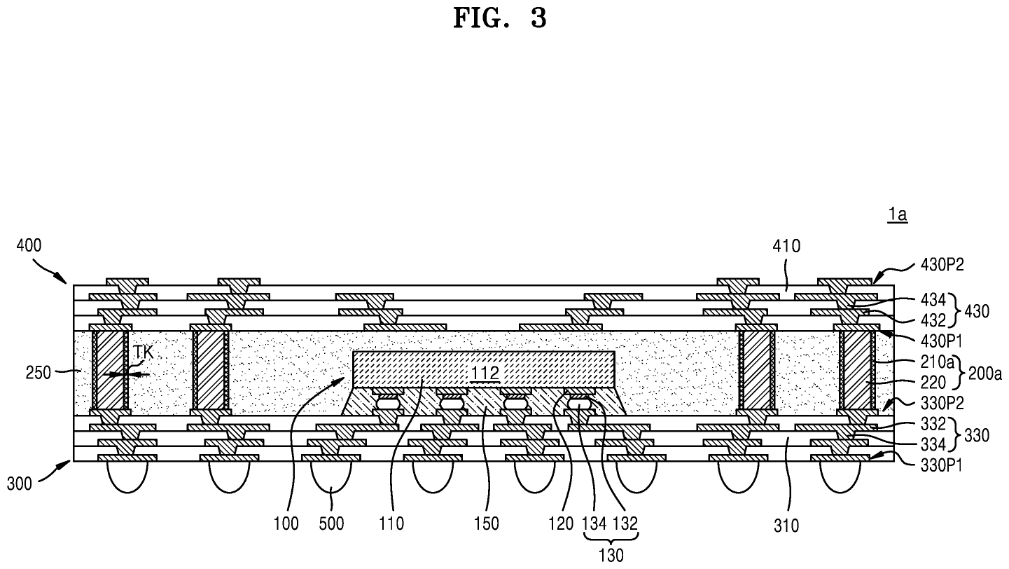

FIG. 3 is a cross-sectional view of a semiconductor package 1a according to an embodiment of the present inventive concept. Semiconductor package 1a may include features similar to those in semiconductor package 1. Therefore, omitted details are understood to be the same as described for corresponding elements elsewhere in the disclosure.

Referring to FIG. 3, the semiconductor package 1a may include the first distribution structure 300, the second distribution structure 400 disposed on the first distribution structure 300, and at least one semiconductor chip 100 disposed between the first distribution structure 300 and the second distribution structure 400. The semiconductor package 1a illustrated in FIG. 3 includes a plurality of connection structures 200a including a conductive antioxidant layer 210a and the conductive post 220.

The plurality of connection structures 200a may include a conductive post 220 and a conductive antioxidant layer 210a surrounding the conductive post 220. For example, the conductive antioxidant layer 210a may surround side surfaces of the conductive post 220. The conductive post 220 may electrically connect the first distribution structure 300 to the second distribution structure 400. The conductive antioxidant layer 210a may cover side surfaces of the conductive post 220. In some embodiments, the conductive antioxidant layer 210a may cover side surfaces of the conductive post 220. The conductive antioxidant layer 210a might not cover the lower surface and the upper surface of the conductive post 220. For example, the conductive antioxidant layer 210a may have a cylindrical shell shape with an open top and an open bottom, and the conductive post 220 may have a cylindrical shape that fills the inside of the conductive antioxidant layer 210a.

An upper surface of the conductive post 220 and the uppermost end (or surface) of the conductive antioxidant layer 210a may be in contact with the second lower surface connection pad 430P1. The lower surface of the second lower surface connection pad 430P1 may cover the upper surface of the conductive post 220 and the uppermost end of the conductive antioxidant layer 210a. The lower surface of the conductive post 220 may be in contact with the first upper surface connection pad 330P2. The lowermost surface of the conductive antioxidant layer 210a may be in contact with the first upper surface connection pad 330P2. The upper surface of the first upper surface connection pad 330P2 may cover the lower surface of the conductive post 220 and the lowermost end (or surface) of the conductive antioxidant layer 210a. The conductive antioxidant layer 210a may be disposed between the conductive post 220 and the encapsulant 250. The conductive antioxidant layer 210a may conformally cover the side surfaces of the conductive post 220.

The conductive antioxidant layer 210a may be in contact with the encapsulant 250, but the conductive post 220 might not be in contact with the encapsulant 250. For example, the conductive antioxidant layer 210a may be disposed between the conductive post 220 and the encapsulant 250, and may be disposed between the first upper surface connection pad 330P2 and the second lower surface connection pad 430P1. The conductive post 220 and the encapsulant 250 may include the conductive antioxidant layer 210a therebetween, and may be apart from each other. For example, the thickness TK of the conductive antioxidant layer 210a may be about 10 nm to about 1 μm.

The semiconductor package 1a according to the present inventive concept may prevent the oxide layer from forming on the surface of the conductive post 220 by covering the side surfaces of the conductive post 220 by using the conductive antioxidant layer 210a, and thus, may prevent the reliability deterioration due to the micro voids forming on an oxide layer.

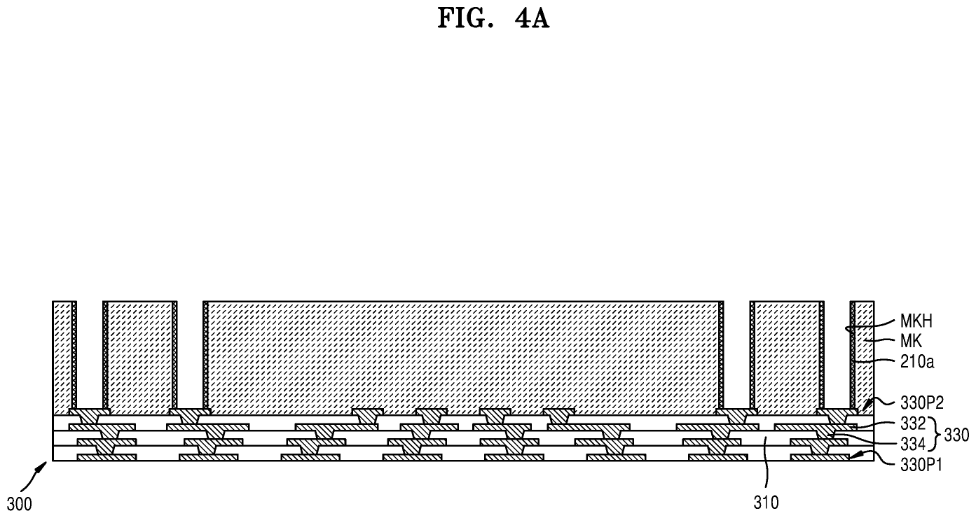

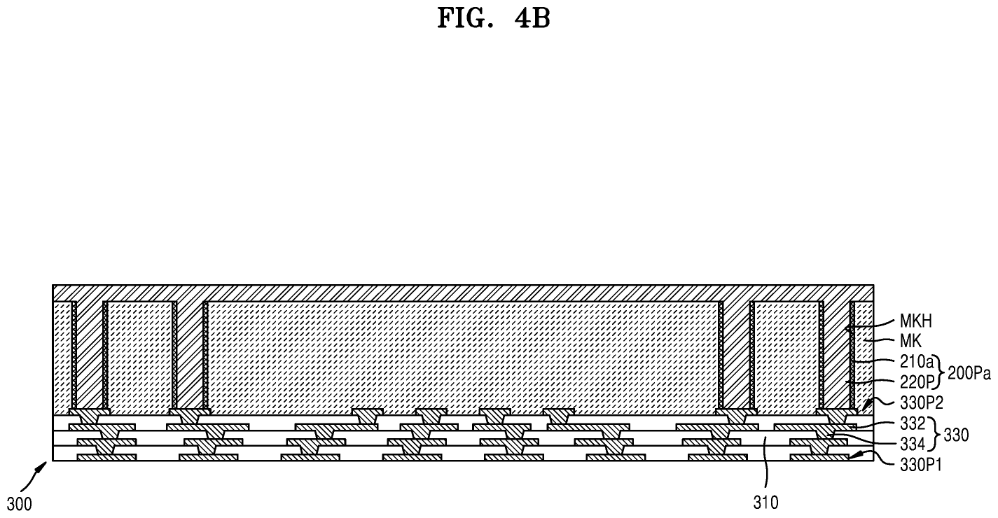

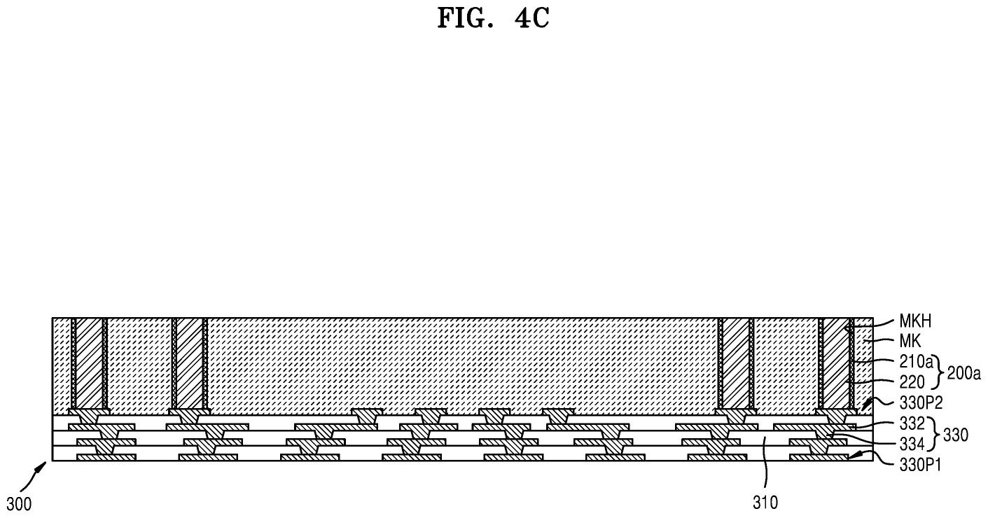

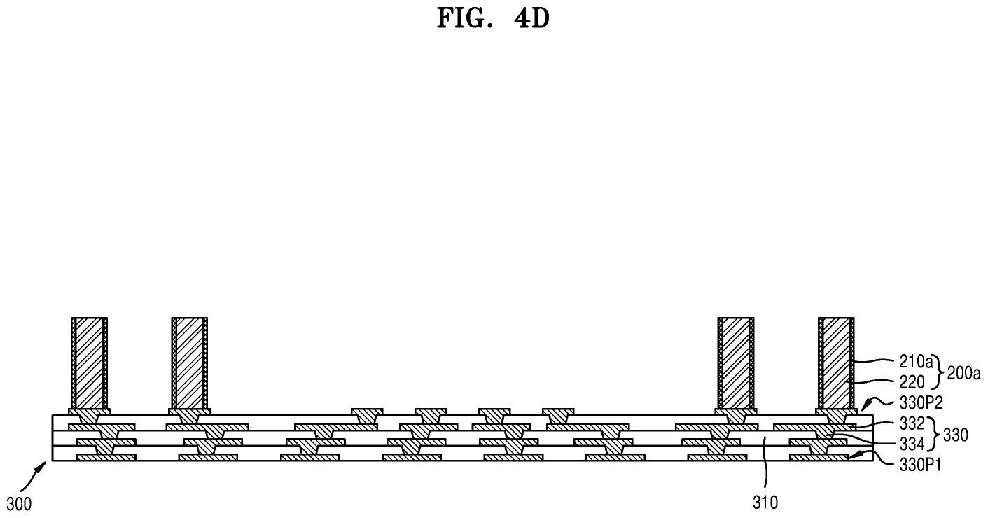

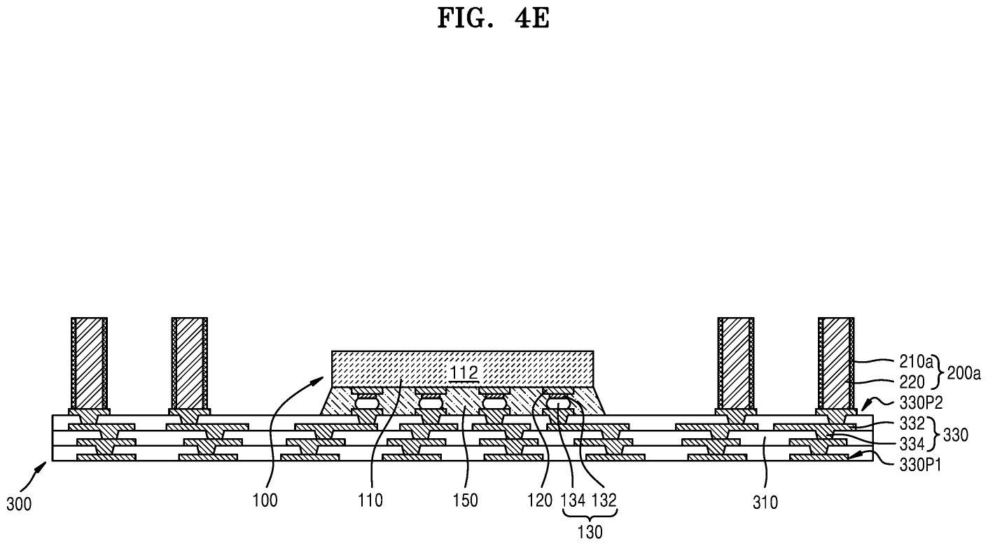

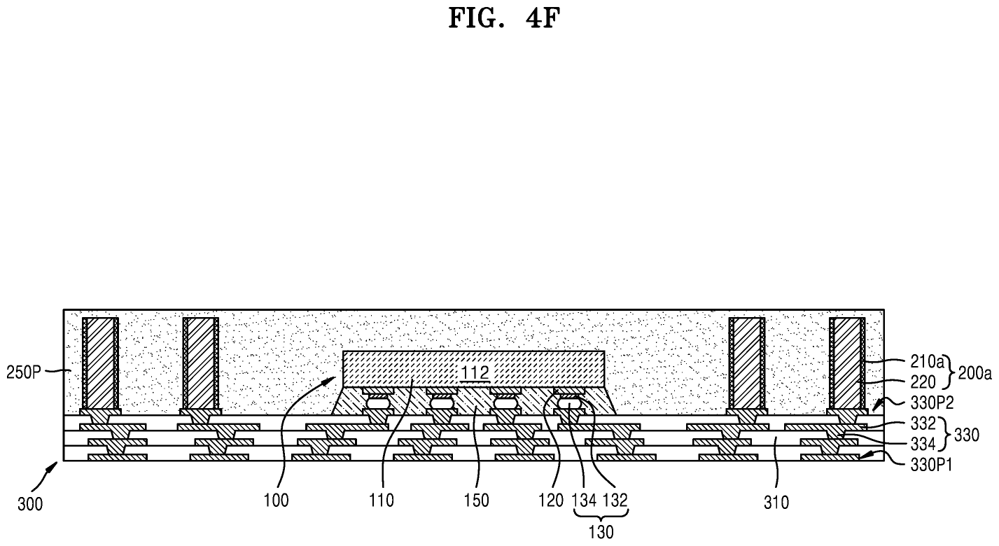

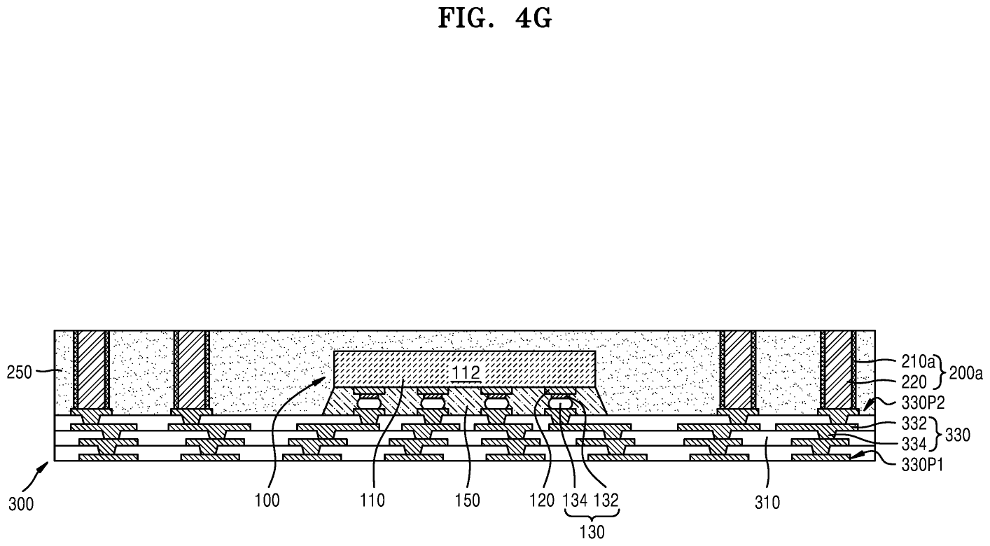

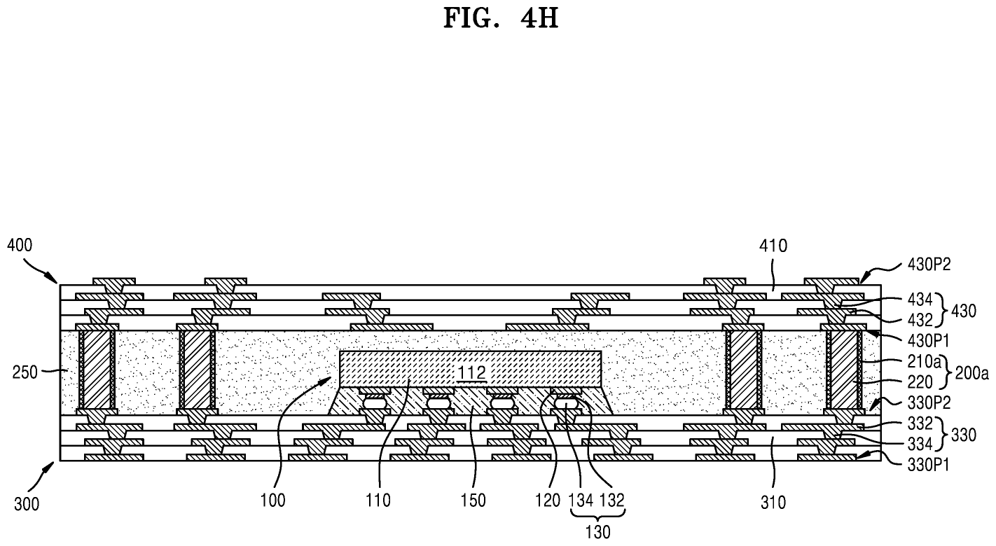

FIGS. 4A through 4H are cross-sectional views illustrating a method of manufacturing the semiconductor package 1a, according to embodiments of the present inventive concept. FIGS. 4A through 4H are cross-sectional views illustrating a method of manufacturing the semiconductor package 1a illustrated in FIG. 3, and omitted details on duplicate descriptions thereof given with reference to FIGS. 2A through 2J, and 3 are understood to be the same as described for corresponding elements elsewhere in the present disclosure.

Referring to FIG. 4A, after the conductive antioxidant layer 210P is formed on the first distribution structure 300, in which the mask pattern MK is formed, with reference to FIGS. 2A through 2C, by removing a portion covering the upper surface of the mask pattern MK and a portion covering the lower surface of each of the plurality of mask holes MKH of the conductive antioxidant layer 210P, the conductive antioxidant layer 210a may be formed. The conductive antioxidant layer 210a may conformally cover the side surface of the mask pattern MK exposed at the inner surface of each of the plurality of mask holes MKH. After the removal process, some of the plurality of first upper surface connection pads 330P2 may be exposed and might not be covered by a portion of the conductive antioxidant layer 210a.

Referring to FIG. 4B, the conductive filling material layer 220P may be formed to cover the mask pattern MK, the conductive antioxidant layer 210a, and some of the plurality of first upper surface connection pads 330P2, and fill the plurality of mask holes MKH. The conductive filling material layer 220P may be formed to fill all of the plurality of mask holes MKH.

Referring to FIGS. 4B and 4C, by removing a portion of the upper surface of the conductive filling material layer 220P to expose the mask pattern MK and the conductive antioxidant layer 210a, the plurality of connection structures 200a may be formed, where the plurality of connection structures 200a includes the conductive antioxidant layer 210a surrounding the conductive post 220 and the conductive post 220. The conductive antioxidant layer 210a may be disposed between the conductive post 220 and the mask pattern MK.

The plurality of connection structures 200a may be formed by removing a portion of the conductive filling material layer 220P using a CMP process. The plurality of connection structures 200a may fill the plurality of mask holes MKH. In the process of forming the plurality of connection structures 200a, a portion of the upper surface of the mask pattern MK may be removed.

Referring to FIGS. 4C and 4D together, the mask pattern MK may be removed from the first distribution structure 300. For example, a bake process for removing moisture from the first distribution structure 300 and the plurality of connection structures 200a may be performed. Additionally or alternatively, plasma treatment for particle removal and surface treatment may be performed.

Referring to FIG. 4E, at least one semiconductor chip 100 including the plurality of chip pads 120 may be disposed on the first distribution structure 300. The semiconductor chip 100 may be disposed on the first distribution structure 300 and spaced apart from the plurality of connection structures 200a in the horizontal direction. In some embodiments, the under-fill layer 150 may be formed to fill a region between at least one semiconductor chip 100 and the first distribution structure 300.

Referring to FIG. 4F, the preliminary encapsulant 250P covering at least one semiconductor chip 100 and the plurality of connection structures 200a may be formed on the first distribution structure 300. To cover the upper surfaces of each of the plurality of connection structures 200a, the preliminary encapsulant 250P may be formed to have an upper surface at a vertical level higher than a level of the upper surfaces of the plurality of connection structures 200a.

Referring to FIGS. 4F and 4G, the encapsulant 250 may be formed by removing a portion of the upper surface of a preliminary encapsulant 250P to expose the plurality of connection structures 200a. In some embodiments, in the process of forming the encapsulant 250, portions of the upper surfaces of the plurality of connection structures 200a may be removed. When an oxide layer is formed by oxidation on a portion of the upper surface of the conductive post 220, which is not covered by the conductive antioxidant layer 210a, the oxide layer generated on the upper surface of the conductive post 220 may be removed together in a process of removing portions of the upper surfaces of the plurality of connection structures 200a and the preliminary encapsulant 250P.

Referring to FIG. 4H, the second distribution structure 400 including the second redistribution insulating layer 410 disposed on the plurality of connection structures 200a and the encapsulant 250 may be formed. The second distribution structure 400 may further include the plurality of second redistribution patterns 430, which include the plurality of second redistribution line patterns 432 and the plurality of second redistribution vias 434.

Accordingly, as illustrated in FIG. 3, by disposing the plurality of external connection terminals 500 to the plurality of first lower surface connection pads 330P1 of the first distribution structure 300, the semiconductor package 1a may be formed.

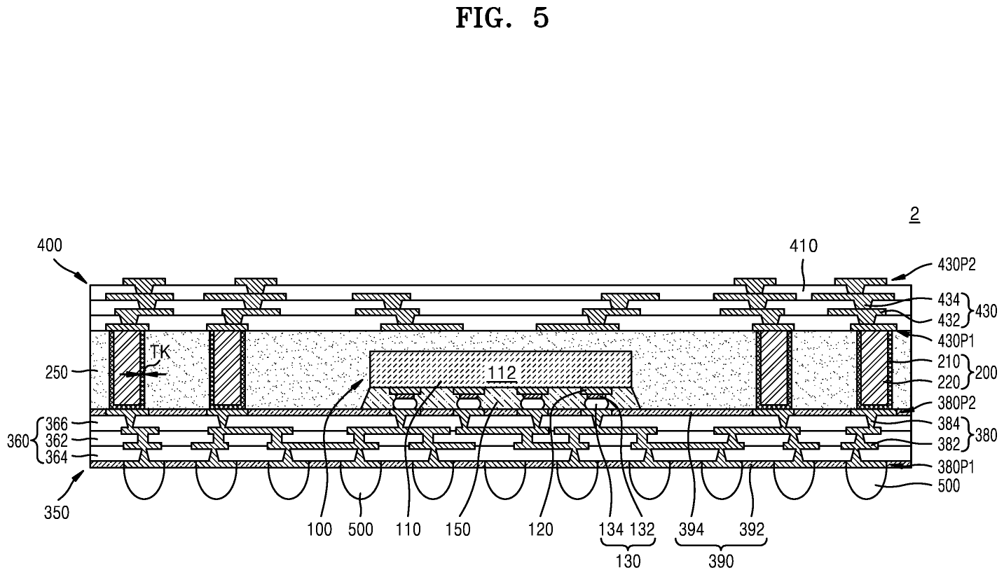

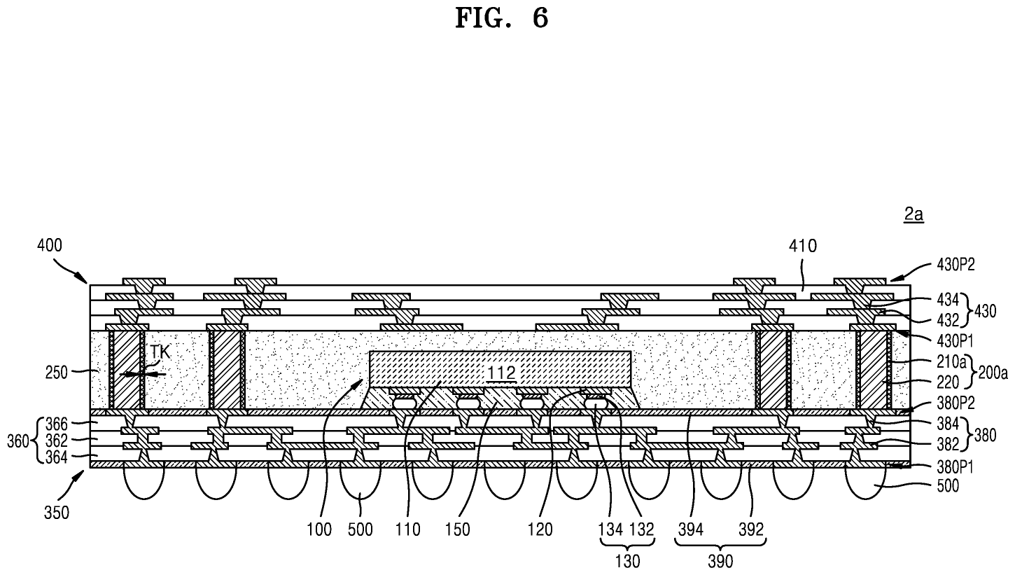

FIGS. 5 and 6 are cross-sectional views of semiconductor package 2 and semiconductor package 2a, respectively, according to embodiments of the present inventive concept. Semiconductor package 2 and semiconductor package 2a may include features similar to those in semiconductor package 1. Therefore, omitted details are understood to be the same as described for corresponding elements elsewhere in the disclosure.

Referring to FIG. 5, the semiconductor package 2 may include a first distribution structure 350, the second distribution structure 400 disposed on the first distribution structure 350, and at least one semiconductor chip 100 disposed between the first distribution structure 350 and the second distribution structure 400. The semiconductor package 2 illustrated in FIG. 5 may include features similar to features of the semiconductor package 1 illustrated in FIG. 1, except the semiconductor package 2 includes the first distribution structure 350.

The first distribution structure 350 may include a printed circuit board. For example, the first distribution structure 350 may include a double-sided printed circuit board or a multi-layer printed circuit board. For example, when the first distribution structure 350 is a multi-layer printed circuit board, distribution layers may be disposed on the lower surface, the upper surfaces, and the inside of the first distribution structure 350. The first distribution structure 350 may include a plurality of first base insulating layers 360, which are stacked on each other, and a plurality of first distribution patterns 380. A distribution layer may be referred to as a region, in which a portion of the plurality of first distribution patterns 380 is disposed at the same vertical level. The distribution layers may be disposed between an upper surface and a lower surface of the first distribution structure 350, and between each of two adjacent first base insulating layers 360 among the plurality of first base insulating layers 360.

Each of the plurality of first base insulating layers 360 may include phenol resin, epoxy resin, and/or polyimide. For example, the plurality of first base insulating layers 360 may include flame retardant 4 (FR4), tetrafunctional epoxy, polyphenylene ether, epoxy/polyphenylene oxide, bismaleimide triazine (BT), thermount, cyanate ester, polyimide, and/or liquid crystal polymer.

The plurality of first base insulating layers 360 may include the core layer 362 and at least one prepreg layer disposed on an upper surface and under a lower surface of the core layer 362. For example, the plurality of first base insulating layers 360 may include the core layer 362, at least one lower prepreg layer 364 disposed on the lower surface of the core layer 362, and at least one upper prepreg layer 366 disposed on the upper surface of the core layer 362. For example, the core layer 362 is disposed between the lower prepreg layer 364 and the upper prepreg layer 366. Each of the core layer 362, the lower prepreg layer 364, and the upper prepreg layer 366 may include the same material. In FIG. 5, one upper prepreg layer 366 is disposed on an upper surface of the core layer 362, and one lower prepreg layer 364 is disposed under a lower surface of the core layer 312, but the embodiment is not limited thereto. For example, two or more upper prepreg layers 366 may be disposed sequentially on the upper surface of the core layer 362, and/or two or more lower prepreg layers 364 may be disposed sequentially on the lower surface of the core layer 362.

In some embodiments, the thickness of each of the upper prepreg layer 366 and the lower prepreg layer 364 may be less than the thickness of the core layer 362. For example, the thickness of the core layer 362 may be about 70 μm to about 1500 μm, and the thickness of each of the upper prepreg layer 366 and the lower prepreg layer 364 may be about 50 μm to about 200 μm.

The plurality of first distribution patterns 380 may include a plurality of first distribution line patterns 382 disposed on an upper surface and under a lower surface of each of the plurality of first base insulation layers 360, and a plurality of first distribution vias 384 penetrating at least one first base insulating layer 360 among the plurality of first base insulating layers 360 and electrically connected to the first distribution line patterns 382 disposed on the distribution layers at different vertical levels. In some examples, a surface of the first distribution line patterns 382 might not be coplanar with a surface of the first base insulation layers 360. The first distribution line patterns 382 at the same vertical level may form one distribution layer.

Each of the plurality of first distribution line patterns 382 may include, for example, electronically deposited (ED) copper foil, rolled-annealed (RA) copper foil, stainless steel foil, aluminum foil, ultra-thin copper foil, sputtered copper, a copper alloy, etc.

The plurality of first distribution line patterns 382 may include a plurality of first lower surface connection pads 380P1 under the lower surface of the first distribution structure 350 and a plurality of first upper surface connection pads 380P2 disposed on the upper surface of the first distribution structure 350. For example, the plurality of first lower surface connection pads 380P1 may be disposed under the lower surface of the lower prepreg layer 364, which is the first base insulating layer 360 at the lowermost layer among the plurality of first base insulating layers 360, and the plurality of first upper surface connection pads 330P2 may be arranged on the upper surface of the upper prepreg layer 366, which is the first base insulating layer 360 at the uppermost layer among the plurality of first base insulating layers 360. The plurality of chip connection members 130 may be disposed on some of the plurality of first upper surface connection pads 380P2, and the remaining ones of the plurality of first upper surface connection pads 380P2 are disposed on a plurality of connection structures 200 may be attached to the others thereof.

In some embodiments, the first distribution structure 300 may include a solder resist layer 390 disposed on the upper surface and under the lower surface the first distribution structure 300. The solder resist layer 390 may include a lower surface solder resist layer 392 disposed under the lower surface of the first distribution structure 350, and an upper surface solder resist layer 394 disposed on the upper surface of the first distribution structure 350. At least a portion of each of the plurality of first lower surface connection pads 380P1 might not be covered by the lower surface solder resist layer 392, but may be exposed to the lower surface of the first distribution structure 350. For example, a lower surface of the plurality of first lower surface connection pads 380P1 may be coplanar with a lower surface of the lower surface solder resist layer 392. The lower surface solder resist layer 392 may cover side surfaces of the plurality of first lower surface connection pads 380P1. At least a portion of each of the plurality of first upper surface connection pads 380P2 might not be covered by the upper surface solder resist layer 394, but may be exposed to the upper surface of the first distribution structure 350. For example, an upper surface of the plurality of first upper surface connection pads 380P2 may be coplanar with an upper surface of the upper surface solder resist layer 394. The upper surface solder resist layer 394 may cover side surfaces of the plurality of first upper surface connection pads 380P2.

In some embodiments, the lower surface solder resist layer 392 disposed under the lower surface of the first distribution structure 350 may be formed, but the upper surface solder resist layer 394 disposed on the upper surface of the first distribution structure 350 might not be formed. For example, solder resist layer 390 may include a lower surface solder resist layer 392.

In some embodiments, each of the lower surface solder resist layer 392 and the upper surface solder resist layer 394 may be formed by doping solder mask insulating ink on the upper surface and the lower surface of the first base insulating layer 360, respectively, by using a screen printing method or an inkjet printing method, and curing the solder mask insulating ink by applying heat, ultraviolet (UV), or infrared (IR). In some embodiments, each of the first lower surface solder resist layer 392 and the upper surface solder resist layer 394 may be formed by doping a photo-imageable solder resist on the entire surface of the upper surface and under entire surface of the lower surface of the first base insulating layer 360, respectively, by using a screen printing method or a spray coating method, or by attaching a film-type solder resist material to the entire surface thereof using a laminating method of a film-type solder resist material. Unnecessary portions of the whole area thereof may be removed by performing an exposure process and a development process, and by curing the whole area thereof by using heat, UV, or IR. For example, the removal process may expose the plurality of first lower surface connection pads 380P1 and the plurality of first upper surface connection pads 380P2 that were covered from the doping process.

In FIG. 5, the plurality of first upper surface connection pads 380P2 are disposed on the upper surface of the first base insulating layer 360 at the uppermost layer among the plurality of first base insulating layers 360, and the plurality of first lower surface connection pads 380P1 are disposed under the lower surface of the first base insulating layer 360 at the lowermost layer, but the embodiment is not limited thereto. For example, the first distribution line pattern 382 covered by the lower surface solder resist layer 392 may be disposed under the lower surface of the first base insulating layer 360 at the lowermost layer among the plurality of first base insulating layers 360, and the first distribution line pattern 382 covered by the upper surface solder resist layer 394 may be disposed on the upper surface of the first base insulating layer 360 at the uppermost layer.

In some embodiments, the plurality of first upper surface connection pads 380P2 and the plurality of first lower surface connection pads 380P1 may be buried (or interposed) in one of the plurality of first base insulating layers 360. For example, the upper surface of the plurality of first upper surface connection pads 380P2 and the upper surface of the upper prepreg layer 366 of the first base insulating layer 360 at the uppermost layer among the plurality of first base insulating layers 360 may be at a same vertical level and may be coplanar with each other. The lower surface of the plurality of first lower surface connection pads 330P1 and the lower surface of the lower prepreg layer 364, which is the first base insulating layer 360 at the lowermost layer among the plurality of first base insulating layers 360 may be at a same vertical level and may be coplanar with each other.

A plurality of external connection terminals 500 may be respectively disposed on the plurality of first lower surface connection pads 380P1. For example, a plurality of external connection terminals 500 may be disposed on the lower surfaces of the plurality of first lower surface connection pads 380P1.

A metal layer may be further formed on the plurality of first upper surface connection pads 380P2 and the plurality of first lower surface connection pads 380P1 among the plurality of first distribution line patterns 382. For example, the metal layer may be disposed on the upper surface of the plurality of first upper surface connection pads 380P2 and under the lower surface of the plurality of first lower surface connection pads 380P1. The metal layer may be formed to improve adhesive force of each of the plurality of first upper surface connection pads 380P2 and the plurality of first lower surface connection pads 380P1, and to reduce contact resistance thereof. For example, the metal layer may be formed by applying a hot air solder leveling (HASL) process, a Ni/Au plating process, etc.

Each of the plurality of first distribution vias 384 may electrically connect two first distribution line patterns 382 arranged on different layers from each other. Each of a plurality of first distribution vias 384 may penetrate at least one first base insulating layer 360. For example, the plurality of first distribution vias 384 may electrically connect the plurality of first upper surface connection pads 380P2 and the plurality of first lower surface connection pads 380P1. For example, the plurality of first upper surface connection pads 380P2 may be electrically connected to the plurality of first lower surface connection pad 380P1 via at least one first distribution line pattern 382 disposed between two adjacent first base insulating layer 360 among the plurality of first base insulating layers 360 and at least two first distribution vias 384 disposed on opposite surfaces (e.g., a top surface and a bottom surface) of the at least one first distribution line pattern 382. The plurality of first distribution vias 384 may include, for example, Cu, Ni, stainless steel, or beryllium copper.

At least one semiconductor chip 100 may be disposed on the first distribution structure 350. In some embodiments, the semiconductor chip 100 may have a face-down arrangement, in which the plurality of chip pads 120 is directed toward the first distribution structure 350, and may be disposed on the upper surface of the first distribution structure 350 via a plurality of chip connection members 130. The plurality of chip connection members 130 may be disposed between the plurality of chip pads 120 of the semiconductor chip 100 and some of the plurality of first upper surface connection pads 380P2 of the first distribution structure 350.

The encapsulant 250 may surround the semiconductor chip 100 on the upper surface of the first distribution structure 350. The encapsulant 250 may fill a region between the first distribution structure 350 and the second distribution structure 400. In some embodiments, an under-fill layer 150 surrounding the plurality of chip connection members 130 may be disposed between the semiconductor chip 100 and the first distribution structure 350. The upper surface of the encapsulant 250 may be in contact with the second redistribution insulating layer 410, and the lower surface of the encapsulant 250 may be in contact with the upper surface solder resist layer 394. The encapsulant 250 may electrically insulate the first distribution structure 350, the second distribution structure 400, and semiconductor chip 100 from each other.

The plurality of connection structures 200 may penetrate the encapsulant 250, and electrically connect the first distribution structure 350 and the second distribution structure 400. The plurality of connection structures 200 may be disposed between the plurality of first upper surface connection pads 380P2 and the plurality of second lower surface connection pads 430P1. The encapsulant 250 may surround the plurality of connection structures 200 and electrically insulate the plurality of connection structures 200 from each other.

An upper surface of the conductive post 220 and the uppermost end (or layer) of the conductive antioxidant layer 210 may be in contact with the second lower surface connection pad 430P1. The lower surface of the second lower surface connection pad 430P1 may cover the upper surface of the conductive post 220 and the uppermost surface of the conductive antioxidant layer 210. The lower surface of the conductive post 220 may be in contact with the conductive antioxidant layer 210. The conductive antioxidant layer 210 may cover the lower surfaces of the conductive post 220. The lower surface of the conductive antioxidant layer 210 may be in contact with the first upper surface connection pad 380P2. The upper surface of the first upper surface connection pad 380P2 may cover the lower surfaces of the conductive antioxidant layer 210. The conductive post 220 may be in contact with the second lower surface connection pad 430P1, but may not be in contact with the first upper surface connection pad 380P2. The conductive posts 220 may include the conductive antioxidant layer 210 therebetween, and may be spaced apart from the first upper surface connection pad 380P2. The conductive antioxidant layer 210 may be disposed in a region between the conductive post 220 and the encapsulant 250, and in a region between the conductive post 220 and the first upper surface connection pad 380P2, and may extend along the region. The conductive antioxidant layer 210 may conformally cover the side surfaces and the lower surface of the conductive post 220.

Referring to FIG. 6, the semiconductor package 2a may include the first distribution structure 350, the second distribution structure 400 disposed on the first distribution structure 350, and at least one semiconductor chip 100 disposed between the first distribution structure 350 and the second distribution structure 400. The semiconductor package 2a illustrated in FIG. 6 may include features similar to features of the semiconductor package 2a illustrated in FIG. 3, except the semiconductor package 2a includes the first distribution structure 350 illustrated in FIG. 5. Therefore, omitted details are understood to be the same as described for corresponding elements elsewhere in the disclosure.

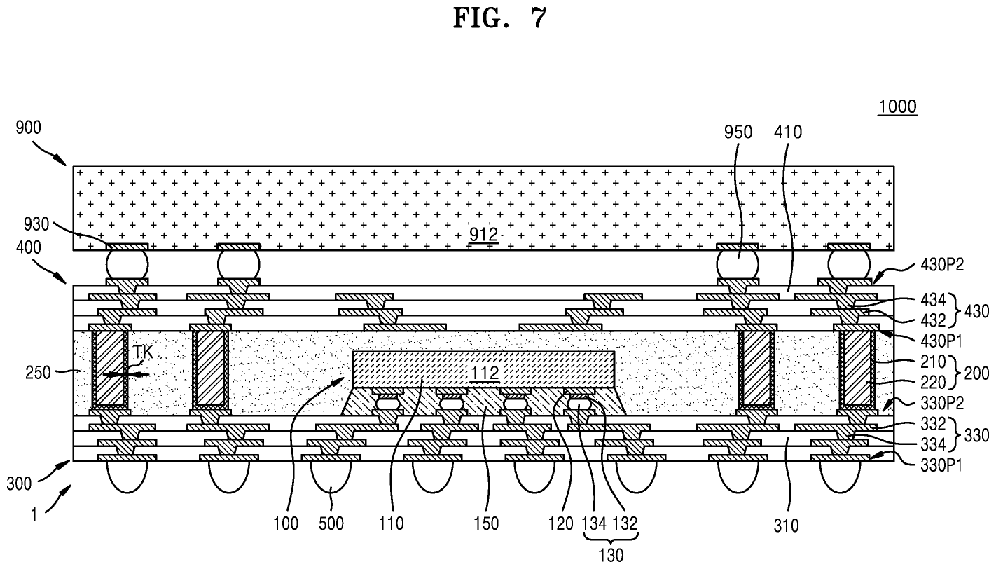

FIGS. 7 through 10 are cross-sectional views of various semiconductor packages, according to embodiments of the present inventive concept.

Referring to FIG. 7, the semiconductor package 1000 may include a lower package (e.g., semiconductor package 1) and an upper package 900 disposed on the lower package (e.g., semiconductor package 1). The semiconductor package 1000 may be a package-on-package (PoP). PoP refers to two or more semiconductor packages that are vertically disposed on each other to for an integrated semiconductor package. Generally, the lower package (e.g., semiconductor package 1) includes logic or processing components and upper package 900 includes a memory component. The lower package may be the semiconductor package 1 described with reference to FIG. 1.

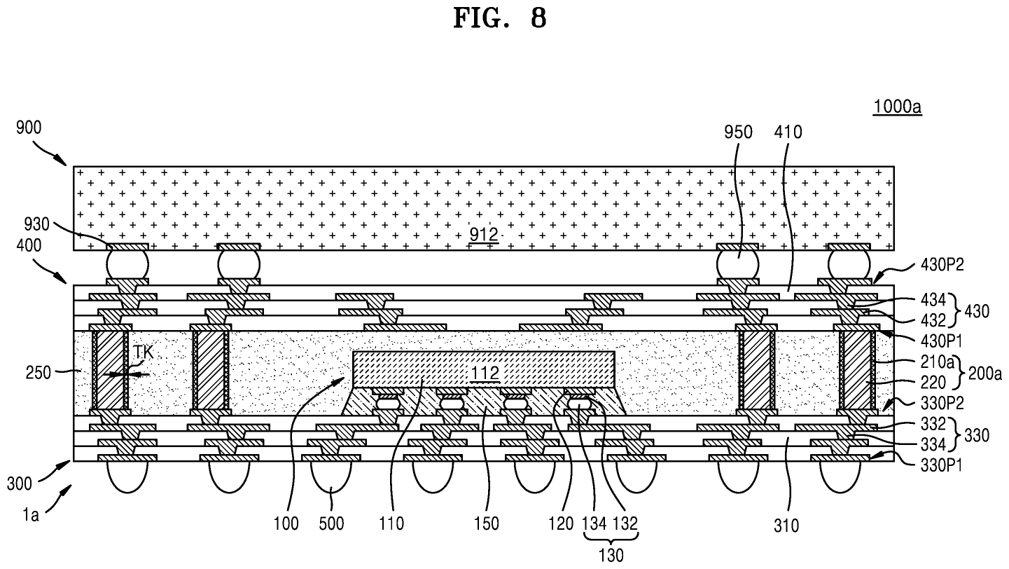

Referring to FIG. 8, a semiconductor package 1000a may include a lower package (e.g., semiconductor package 1a) and an upper package 900 disposed on the lower package. The semiconductor package 1000a may be a PoP. The lower package may be the semiconductor package 1a described with reference to FIG. 3.

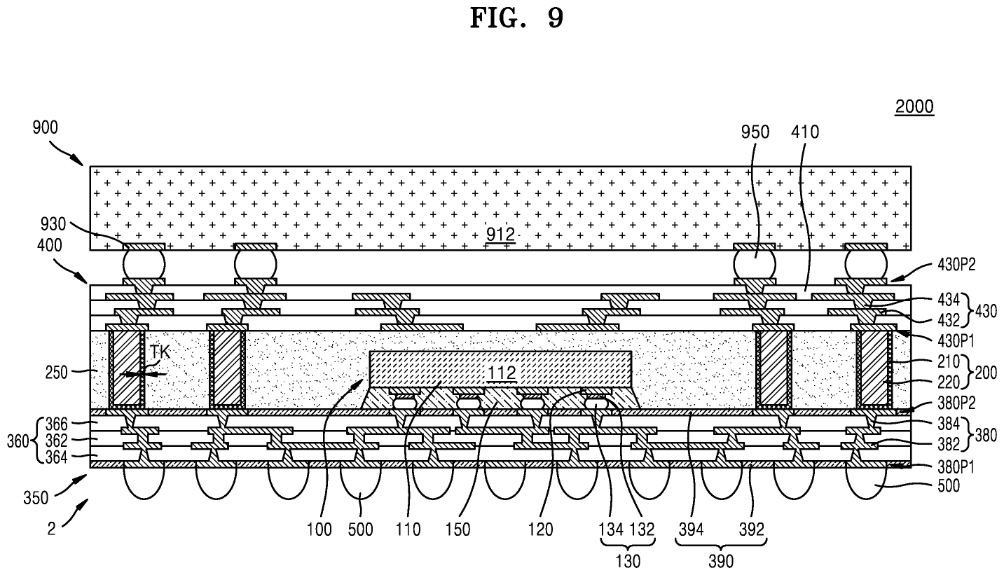

Referring to FIG. 9, a semiconductor package 2000 may include a lower package (e.g., semiconductor package 2) and the upper package 900 disposed on the lower package. The semiconductor package 2000 may be a PoP. The lower package may be the semiconductor package 2 described with reference to FIG. 5.

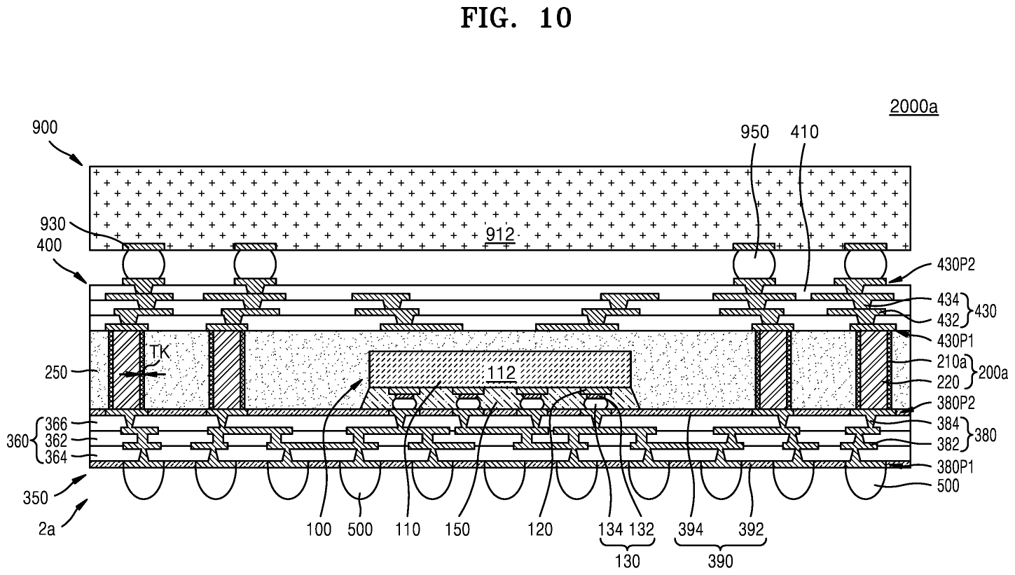

Referring to FIG. 10, a semiconductor package 2000a may include a lower package (e.g., semiconductor package 2a) and the upper package 900 disposed on the lower package. The semiconductor package 2000a may be a PoP. The lower package may be the semiconductor package 2a described with reference to FIG. 6.

Referring to FIGS. 7 through 10, the upper package 900 may include an upper semiconductor chip including an upper semiconductor device 912 and a plurality of upper connection pads 930. For example, a lower surface of the plurality of upper connection pads 930 may be coplanar with a bottom surface of the upper package 900. The upper package 900 may be electrically connected to the lower packages (e.g., semiconductor packages 1, 1a, 2, and 2a) via a plurality of package connection terminals 950 disposed between the plurality of upper connection pads 930 and the plurality of second upper surface connection pads 430P2. The upper package 900 may be disposed on each of the lower packages so that the plurality of upper connection pads 930 is directed toward the lower packages. For example, the upper package 900 may be electrically connected to the plurality of first redistribution patterns 330 of the first distribution structure 300 or the plurality of first distribution patterns 380 of the first distribution structure 350 via the plurality of package connection terminals 950 electrically connected to the plurality of upper connection pads 930, the plurality of second redistribution patterns 430, and the plurality of connection structures 200. For example, the upper semiconductor device 912 of the upper package 900 may be electrically connected to the plurality of upper connection pads 930, the plurality of package connection terminals 950, the plurality of second redistribution patterns 430, the plurality of connection structures 200, and the plurality of first redistribution patterns 330 or the plurality of first distribution patterns 380. In some embodiments, the upper semiconductor device 912 may include a memory device, and the upper semiconductor chip may include a memory semiconductor chip. For example, the memory device may include a non-volatile memory device, such as a flash memory, PRAM, MRAM, FeRAM, and RRAM. The flash memory, in some embodiments, may include a volatile memory device, such as DRAM and SRAM.

The upper package 900 may include one or a plurality of upper semiconductor chips. The upper semiconductor chip may be mounted in the upper package 900 in a flip chip manner, or may be electrically connected thereto via a bonding wire and mounted thereon by using a die attach film (DAF). The upper package 900 may include a plurality of upper semiconductor chips spaced apart from each other in the horizontal direction, and may include a plurality of upper semiconductor chips stacked in the vertical direction. Alternatively, the upper package 900 may include a plurality of upper semiconductor chips electrically connected to each other via an electrode, and stacked in the vertical direction. Alternatively, the upper package 900 may also include one semiconductor chip.

For example, the upper package 900 may include at least one upper semiconductor chip including the upper semiconductor device 912, and may correspond to any type of a semiconductor package including the plurality of upper connection pads 930 on the lower surface of the upper package 900 to be electrically connected to the lower packages (e.g., semiconductor packages 1, 1a, 2, and 2a).

While the inventive concept has been particularly shown and described with reference to embodiments thereof, it will be understood that various changes in form and details may be made therein without departing from the spirit and scope of the following claims.

What is claimed is:

1. A semiconductor package comprising:
a first distribution structure including a plurality of first distribution patterns disposed between a plurality of first lower surface connection pads and a plurality of first upper surface connection pads, and a first base insulating layer surrounding the plurality of first distribution patterns;
a second distribution structure including a plurality of second distribution patterns disposed between a plurality of second lower surface connection pads and a plurality of second upper surface connection pads, and a second base insulating layer surrounding the plurality of second distribution patterns;
a semiconductor chip disposed between the first distribution structure and the second distribution structure;
an encapsulant filling a space between the first distribution structure and the second distribution structure and surrounding the semiconductor chip; and
a plurality of connection structures penetrates the encapsulant and disposed adjacent to the semiconductor chip,
wherein a connection structure of the plurality of connection structures includes a conductive post extending in a vertical direction to electrically connect a first upper surface connection pad of the plurality of first upper surface connection pads and a second lower surface connection pad of the plurality of second lower surface connection pads, and
wherein the connection structure includes a conductive antioxidant layer covering side surfaces of the conductive post.

2. The semiconductor package of claim 1, wherein the conductive antioxidant layer is disposed between the conductive post and the encapsulant.

3. The semiconductor package of claim 1, wherein the conductive antioxidant layer covers the side surfaces and a lower surface of the conductive post.

4. The semiconductor package of claim 3, wherein the conductive antioxidant layer has a cylindrical shell shape with an open top and a closed bottom, and
the conductive post has a circular pillar shape filling an inside of the cylindrical shell shape.

5. The semiconductor package of claim 1, wherein the conductive antioxidant layer has a thickness ranging from 10 nm to 1 μm.

6. The semiconductor package of claim 1, wherein first portions of upper surfaces of the plurality of first upper surface connection pads are covered by the encapsulant.

7. The semiconductor package of claim 6, wherein a lower surface of the conductive post and a lowermost surface of the conductive antioxidant layer are in contact with an upper surface of the first upper surface connection pad.

8. The semiconductor package of claim 6, wherein second portions of the upper surfaces of the plurality of first upper surface connection pads are covered by the conductive antioxidant layer.

9. The semiconductor package of claim 1, wherein each of the first distribution structure and the second distribution structure comprises a redistribution structure formed by performing a redistribution process.

10. The semiconductor package of claim 1, wherein the first distribution structure comprises a printed circuit board, and
the second distribution structure comprises a redistribution structure formed by a rewiring process.

11. A semiconductor package comprising:
a first distribution structure including a plurality of first distribution patterns disposed between a plurality of first lower surface connection pads and a plurality of first upper surface connection pads, and a first base insulating layer surrounding the plurality of first distribution patterns;
a second distribution structure including a plurality of second distribution patterns disposed between a plurality of second lower surface connection pads and a plurality of second upper surface connection pads, and a second base insulating layer surrounding the plurality of second distribution patterns;
a semiconductor chip disposed between the first distribution structure and the second distribution structure, wherein a plurality of chip pads is disposed on a bottom surface of the semiconductor chip;
a plurality of connection structures connecting a first group of the plurality of first upper surface connection pads to a first group of the plurality of second lower surface connection pads and disposed adjacent to the semiconductor chip, wherein a connection structure of the plurality of connection structures includes a conductive post extending in a vertical direction and a conductive antioxidant layer covering side surfaces of the conductive post;
a plurality of chip connection members connecting a second group of the plurality of first upper surface connection pads and the plurality of chip pads; and
an encapsulant surrounding the plurality of connection structures and the semiconductor chip, filling a space among the first distribution structure, the second distribution structure, and the conductive antioxidant layer, and spaced apart from the conductive post.

12. The semiconductor package of claim 11, wherein first portions of upper surfaces and portions of side surfaces of the first group of the plurality of first upper surface connection pads are covered by the encapsulant.

13. The semiconductor package of claim 12, wherein second portions of the upper surfaces of the first group of the plurality of first upper surface connection pads are covered by the conductive antioxidant layer.

14. The semiconductor package of claim 12, wherein second portions of the upper surfaces of the first group of the plurality of first upper surface connection pads are covered by a lower surface of the conductive post and a lowermost surface of the conductive antioxidant layer.

15. The semiconductor package of claim 12, wherein first portions of the plurality of second lower surface connection pads are covered by the encapsulant, and
wherein second portions of the plurality of second lower surface connection pads are covered by an upper surface of the conductive post and an uppermost surface of the conductive antioxidant layer.

16. The semiconductor package of claim 11, wherein the plurality of first upper surface connection pads protrudes from an upper surface of the first base insulating layer, and
wherein a lower surface of the plurality of second lower surface connection pads and a lower surface of the second base insulating layer are coplanar with each other.

17. The semiconductor package of claim 11, wherein an upper surface of the encapsulant, an uppermost surface of the conductive antioxidant layer, and an upper surface of the conductive post are at a same vertical level and are coplanar with each other.

18. A semiconductor package comprising:
a first redistribution structure including a plurality of first distribution patterns disposed between a plurality of first lower surface connection pads and a plurality of first upper surface connection pads, and a first redistribution insulating layer adjacent to the plurality of first distribution patterns;
a semiconductor chip disposed on the first redistribution structure, wherein a plurality of chip pads is disposed on a bottom surface of the semiconductor chip;
a second redistribution structure disposed on the semiconductor chip and the first redistribution structure, and is spaced apart from the semiconductor chip in a vertical direction, wherein the second redistribution structure includes a plurality of second redistribution patterns including a plurality of second lower surface connection pads, a plurality of second upper surface connection pads, and a second redistribution insulating layer adjacent to the plurality of second redistribution patterns;
a plurality of connection structures disposed adjacent to the semiconductor chip and connecting a first portion of the plurality of first upper surface connection pads to the plurality of second lower surface connection pads, wherein a connection structure of the plurality of connection structures includes a conductive post extending in the vertical direction and a conductive antioxidant layer covering side surfaces and a lower surface of the conductive post;
a plurality of chip connection members connecting a second portion of the plurality of first upper surface connection pads to the plurality of chip pads, wherein a chip connection member of the plurality of chip connection members includes an under bump metal (UBM) layer disposed on the plurality of chip pads and a conductive cap covering the UBM layer;
a plurality of external connection terminals respectively connected to the plurality of first lower surface connection pads; and
an encapsulant in a space between the first redistribution structure and the second redistribution structure, covering the plurality of connection structures, the semiconductor chip, and the conductive antioxidant layer, and spaced apart from the conductive post.

19. The semiconductor package of claim 18, wherein the conductive antioxidant layer comprises a metal, an alloy, or conductive metal nitride.

20. The semiconductor package of claim 18, wherein the encapsulant comprises an epoxy mold compound including a filler.
